(19) United States
(12) Patent Application Publication
(10) Pub. No.: US 2024/0427239 A1
(43) Pub. Date: Dec. 26, 2024

(54) ORGANOTIN ALKOXIDES AS PRECURSORS FOR PATTERNING COMPOSITIONS WITH FLUORINE SUBSTITUENTS AND CARBON-CARBON DOUBLE BONDS

(71) Applicant: Inpria Corporation, Corvallis, OR (US)

(72) Inventors: Robert E. Jilek, Philomath, OR (US); Christopher J. Reed, Corvallis, OR (US)

(21) Appl. No.: 18/731,702

(22) Filed: Jun. 3, 2024

Related U.S. Application Data
(60) Provisional application No. 63/521,158, filed on Jun. 15, 2023.

(51) Int. Cl. G03F 7/027; C08F 30/04; G03F 7/004

(52) U.S. Cl. CPC G03F 7/027; C08F 30/04; G03F 7/0044; G03F 7/0048

(57) ABSTRACT

Organotin compositions suitable for radiation based patterning have ligands providing fluorinated groups and unsaturated carbon-carbon bonds, such as C═C bonds. The fluorinated groups and unsaturated carbon-carbon bonds may or may not be located on the same ligand. Blends of precursors with different ligands provide added flexibility with respect to precursor design. Fluorinated organometallic compounds can be represented by the formula R^{UF}Sn(OR′)₃, wherein R^{UF} is an organo group with 1 to 31 carbon atoms with at least one C═C bond and at least one fluorine atom bonded to a carbon, with the organo group forming a C—Sn bond, wherein R′ is an organo group with 1 to 10 carbon atoms. Precursors are suitable for solution based deposition or vapor based deposition.

### CROSS REFERENCE TO RELATED APPLICATIONS

This application claims priority to copending U.S. provisional patent application 63/521,158 filed Jun. 15, 2023 to Jilek et al., entitled “Selective Synthesis of Organotin Alkoxides,” incorporated herein by reference.

### FIELD OF THE INVENTION

The invention relates to organometallic tin based photopatternable materials having organic ligands involving fluorine-carbon bonds and carbon-carbon double bonds, as well as hydrolysable ligands. The fluorine-carbon bonds and the carbon-carbon double bonds may or may not be in the same ligands, and in some embodiments, one or more carbon atoms with double bonds may be fluorinated. The invention further relates to solutions for coating these compositions and to coatings formed from these compositions, generally following hydrolysis of hydrolysable ligands.

### BACKGROUND OF THE INVENTION

Organometallic compounds suitable for radiation based patterning can be provided with metal ions in solution or in vapor forms for deposition of thin films. Organotin compounds can provide high EUV absorption and radiation sensitive tin-ligand bonds that can be used to lithographically pattern thin films. The manufacture of semiconductor devices at ever shrinking dimensions with EUV radiation requires new materials with wide process latitude to achieve required patterning resolutions and low defect densities.

### SUMMARY OF THE INVENTION

In a first aspect, the invention pertains to a composition comprising a blend of R¹SnL¹₃ and R²SnL²₃, where R¹ and R² are independently an organo group with 1 to 31 carbon atoms that are different from each other and collectively comprise at least one carbon atom that has at least one unsaturated carbon-carbon bond and at least one carbon atom that has a C—F bond, with each organo group forming a C—Sn bond, wherein R¹SnL¹₃ and R¹SnL¹₃ each comprise at least about 1% of the total Sn atoms in the composition and L¹ and L² are independently selected hydrolysable ligands. A photoresist composition can comprise an organic solvent and the composition comprising a blend of R¹SnL¹₃ and R²SnL²₃.

In a further aspect, the invention pertains to a fluorinated organometallic compound represented by the formula R^{UF}Sn(OR′)₃, wherein R^{UF} is an organo group with 1 to 31 carbon atoms with at least one C═C bond and at least one fluorine atom bonded to a carbon, with the organo group forming a C—Sn bond, wherein R′ is an organo group with 1 to 10 carbon atoms. A photoresist composition comprising an organic solvent and the fluorinated organometallic compound.

In another aspect, the invention pertains to a method for synthesizing a fluorinated organometallic compound represented by the formula R^{UF}Sn(OR′)₃, where R^{UF} is an organo group with 1 to 31 carbon atoms with unsaturated C—C bonds and at least one fluorine atom bonded to a carbon, wherein R^{UF} forms a C—Sn bond and R′ is an organo group with 1 to 10 carbon atoms. The method comprises reacting R^{UF}X with Sn₂(OR′)₄ or MSn(OR′)₃ under visible or ultraviolet light where X is Cl, Br or I.

Additionally, the invention pertains to a composition comprising R^{B}SnO_{(3/2-x/2)}(OH)ₓ, where 0<x<3 and R^{B} represents an organo group or a blend of ligands each being an organo group, where each organo group independently has 1 to 31 carbon atoms, collectively the organo group(s) have at least one carbon atom that has a C═C bond and at least one carbon atom has a C—F bond, and each organo group forming a C—Sn bond, the composition comprising an oxo-hydroxo network. A coated substrate can comprise a substrate with a surface and the composition comprising R^{B}SnO_{(3/2-x/2)}(OH)ₓ on the surface of the substrate.

Furthermore, the invention pertains to a method for forming a patterning composition on a substrate surface, in which the method comprises coating a solution onto the substrate surface, and removing the solvent to form a coating. The solution can comprise a solvent and a dissolved blend of R¹SnL¹₃ and R²SnL²₃, where R¹ and R² are independently an organo group with 1 to 31 carbon atoms that are different from each other and collectively comprise at least one unsaturated carbon-carbon bond and at least 1 fluorine atom bound to a carbon atom, with the organo group forming a C—Sn bond, wherein R¹SnL¹₃ and R²SnL²₃ each comprise at least about 1% of the total Sn atoms in the composition and L¹ and L² are independently selected hydrolysable ligands. The resulting coating can comprise R^{B}SnO_{(3/2-x/2)}(OH)ₓ, where 0<x<3 and R^{B} is a blend of R¹ and R² ligands.

In some aspects, the invention pertains to a method for forming a radiation-patternable coating on a substrate surface, in which the method comprises simultaneously or sequentially reacting organotin precursor with a counter-reactant to form a patternable organometallic composition on the surface of the substrate, wherein the organotin precursor and the counter-reactant are supplied as vapors. Generally, the organotin precursor vapors comprise R¹SnL¹₃ and R²SnL²₃, where R¹ and R² are independently an organo group with 1 to 31 carbon atoms that are different from each other and collectively comprise at least one unsaturated carbon-carbon bond and at least 1 fluorine atom bound to a carbon atom, with the organo group forming a C—Sn bond, wherein R¹SnL¹₃ and R²SnL²₃ each comprise at least about 1% of the total Sn atoms in the composition and L¹ and L² are independently selected hydrolysable ligands. The counter-reactant can comprise water, molecular oxygen, and/or other oxygen donating compound; and forming a radiation-patternable coating on the substrate surface wherein the radiation-patternable coating comprises R^{B}SnO_{(3/2-x/2)}(OH)ₓ, where 0<x<3 and R^{B} is a blend of R¹ and R² ligands.

In other aspects, the invention pertains to a composition comprising a blend of R¹SnL¹₃ and R²SnL²₃, wherein R¹ and R² are independently an organo group comprising from 1 to 31 carbon atoms, that are different from each other and collectively comprise at least one fluorinated group and a C═C bond, and each forms a C—Sn bond, wherein R^{F}SnL¹₃ comprises at least about 1% of the total Sn atoms in the composition, and wherein L¹ and L² are independently selected hydrolysable ligands. A photoresist composition can comprise an organic solvent and the composition comprising a blend of R¹SnL¹₃ and R²SnL²₃.

In further aspects, the invention pertains to a fluorinated organometallic compound represented by the formula R^{UF}SnL₃, wherein R^{UF} is an organo group having from 1 to 31 carbon atoms with at least one carbon atom that forms both a C═C bond and a C—F bond, and wherein R^{UF} forms a C—Sn bond, and wherein L is a hydrolysable ligand.

Additionally, the invention pertains to a fluorinated organotin composition comprising an R^{UF}—Sn bond, wherein R^{UF} is an organo group having from 1 to 31 carbon atoms with at least one carbon atom that forms both a C═C bond and a C—F bond, and the R^{UF}—Sn bond comprises a C—Sn bond.

### BRIEF DESCRIPTION OF DRAWINGS

FIG. 1 is a plot of normalized FTIR peak areas as a function of bake temperature for fluorinated and non-fluorinated organotin resists.

### DETAILED DESCRIPTION OF THE INVENTION

New synthetic routes to organotin trialkoxide compositions have provided effective synthesis routes for organo tin compositions that have organo ligands that have been elusive with respect to a synthesis pathway with good yields and efficient processing under the objective of practical commercial materials. The ability to form effectively a broader range of compositions suitable for commercialization has provided the ability to form blends of organo tin patterning materials that can provide desirable properties to coatings of patterning materials. In particular, ligands with fluorine atoms can provide enhanced absorption of radiation used for patterning, which can improve patterning results. At the same time, fluorine atoms can stabilize the carbon-tin bonds to enhance thermal stability of the ligands. Also, ligands with carbon-carbon double bonds can also exhibit greater radiation absorption. Particularly desirable ligands have both unsaturated carbon-carbon bonds along with fluorine atoms in the same ligand and optionally involving the same carbon atoms, and the synthesis of such compositions are exemplified. The effective synthesis methods can directly synthesize trialkoxides, which are convenient precursors for coating formation. The alkoxide ligands are generally hydrolyzed during formation of the patterning material on a substrate. In compositions formed with a blend of organo ligands, the material formed after solvent removal forms an integrated oxo-hydroxo network with a distribution of tin atoms having corresponding organo ligands. In this way, a patternable coating can be designed to impart desired properties based on the selected blends of ligands. The availability of improved synthesis pathways enables the practical formation of desirable ligands that can correspondingly be included in blends to form materials with a mixture of ligands that overall provide a desired balance of properties.

With respect to the blend of precursors, the fluorine atoms can be effective to provide thermal stability. The C—F bonds generally have a stronger binding energy than C—H bonds, which can provide for enhanced thermal stability relative to non-fluorinated precursors. Also, fluorine has increased EUV absorption relative to the hydrogen atoms that they generally replace. Carbon-carbon double bonds, for example, within alkenes and derivatives thereof, can provide for increased reactivity of the ligand and can lead to thermal instability. Thus, the presence of C—F bonds can improve the thermal stability of the alkene-containing ligands. In the organometallic material formed following solvent removal, the collective effects of the ligand properties become more complex as the material involves an interconnected oxo-hydroxo network.

As used herein, and as generally consistent with usage in this field, “organotin,” “hydrocarbyl tin”, and “alkyl tin” terms can be used interchangeably, and likewise “monoalkyl” can be used interchangeably with “monoorgano” or “monohydrocarbyl”. The “alkyl” (i.e., “organo”) ligands suggest bonding to the tin via Sn—C bonds wherein the carbon is generally sp3 or sp2 hybridized and forms a bond that is generally not hydrolysable through contact with water. The “alkyl” group can optionally have internal unsaturated bonds and hetero-atoms, i.e., distinct from carbon and hydrogen, that are not involved in bonding with the tin. A chemical group bonded to a metal atom is generally referred to as a ligand in the art. A reference to a “hydrolysable ligand” generally refers to a ligand bound to the Sn with a hydrolysable bond, such as an alkoxide ligand which is bound at an oxygen atom with an organo substituent on the oxygen or an amide ligand which is bound at a nitrogen atom with an organo substituent(s) on the nitrogen. Synthesis methods described herein yield monoalkyl tin trialkoxides in high yield and with low (non-tin) metal and polyalkyltin (e.g., dialkyltin, trialkyltin) contaminants following straightforward purification. The organometallic precursor synthesis approaches are amenable for efficient scale up for commercial production, and the reactions are straightforward and can be performed as a single pot synthesis.

For the precursor synthesis, individual precursors can be synthesized by an appropriate efficient synthesis protocol for the particular organo ligand, and the individual precursors can be blended if desired. Applicant has developed multiple synthesis protocols that are generally effective and efficient, such as with respect to cost, time, or other pragmatic factors, for certain ligands. Since many synthesis procedures involve reactivity of halide reactants, fluorine containing ligands can be prone to formation of undesirable by-products and therefore purification of the desired product is generally required, resulting in lower yields and inefficiencies. The ability to form compositions with fluorine containing ligands in an efficient process with appropriate yields has corresponding commercial significance.

With respect to fluorine containing organo ligands, synthesis protocols have been discovered based on oxidative stannylation starting from Sn(II) alkoxide, and the methods offer high selectivity and efficiency. The new synthesis methods are based on reaction of tin (II) alkoxide with a potassium alkoxide to form an intermediate bimetallic potassium tin(II) alkoxide composition or other similar alkali tin trialkoxide, followed by subsequent reaction of the intermediate bimetallic composition with an alkyl halide to form a monoalkyltin trialkoxide composition. The methods described herein can provide for high selectivity and yield and enable the preparation of monoalkyltin trialkoxide compositions without the need to perform ligand exchange or conversion reactions, for example, conversion of a monoalkyltin triamide to a monoalkyltin trialkoxide. The reactions described herein can be useful for preparing monoalkyltin trialkoxides having primary or secondary Sn—C bonds. Furthermore, the reactions described herein can be useful in preparing organotin compounds with fluorinated organo ligands, e.g., R^{F}SnL₃ compounds where R^{F} is an alkyl ligand substituted with one or more fluorine atoms. Owing to the presence of fluorine within the alkyl ligand, the R^{F}SnL₃ compounds can be prepared via visible or UV light driven reactions without the use of a metal-tin composition while still achieving high specificity for the monoalkyl tin product.

Organotin compounds, particularly monoalkyltin trialkoxide and triamide compounds, have found use as high-performance photoresists for EUV lithography. The use of alkyl tin compounds in high performance radiation-based patterning compositions is described, for example, in U.S. Pat. No. 9,310,684 to Meyers et al., entitled “Organometallic Solution Based High Resolution Patterning Compositions,” incorporated herein by reference. Refinements of these organometallic compositions for patterning are described in U.S. Pat. No. 10,642,153 to Meyers et al., entitled “Organometallic Solution Based High Resolution Patterning Compositions and Corresponding Methods,” and 10,228,618 to Meyers et al. (hereinafter the '618 patent), entitled “Organotin Oxide Hydroxide Patterning Compositions, Precursors, and Patterning,” both of which are incorporated herein by reference.

The compositions synthesized herein can be effective precursors for forming the alkyl tin oxo-hydroxo compositions that are advantageous for high resolution patterning, for example in extreme ultraviolet (EUV), ultraviolet (UV), electron-beam lithography. The alkyl tin precursor compositions comprise a ligand that can be hydrolyzed with water or other suitable reagent under appropriate conditions to form the monoalkyl tin oxo-hydroxo patterning compositions, which, when fully hydrolyzed, can be represented by the formula RSnO_{(1.5-(x/2))}(OH)ₓ where 0<x≤3. It can be convenient to perform the hydrolysis to form the oxo-hydroxo compositions in situ, such as during deposition and/or following initial coating formation. While alkyl tin triamides and alkyl tin triacetylides described, for example, in the above-referenced '618 patent, can be used under hydrolyzing conditions for forming radiation sensitive coatings for patterning, it can be desirable to use alkyl tin trialkoxides as part of the film-forming compositions. Direct synthesis of alkyl tin trialkoxides are described herein.

Monoalkyl tin compositions can generally be represented by the formula RSnL₃, where R is an organo group (i.e., ligand) and L is a hydrolysable ligand. For processing to form radiation patternable coatings, L is generally hydrolyzed before or during or shortly after (e.g., in-situ) deposition to result in a coating comprising a polymeric organotin oxo-hydroxo composition on a substrate wherein the Sn—R bonds remain substantially intact. As a result, a radiation patternable coating having radiation-sensitive Sn—R bonds can be realized. Once the hydrolysis is completed on the substrate surface, the compositions can be considered an integrated material in which the tin atoms are distributed within an oxo-hydroxo network connecting the material. For formation of radiation patternable coatings from blends of distinct monoalkyltin compositions, a similar oxo-hydroxo network is realized wherein the tin atoms having different R groups are distributed throughout the oxo-hydroxo network to form an integrated material. In this context, reorganization free energies and other collective effects can influence the individual reactivities.

The syntheses described herein are advantageous for efficient formation of R—Sn bonds with a wide selection of R groups having heteroatom(s) that can offer improvements in thermal stability and/or photosensitivity over R groups having non-substituted alkyl groups. While not wanting to be limited by theory, it is generally believed that the presence of R ligands imparts solubility of the as-deposited films by hindering extended network formation and condensing of the organotin film. Irradiation of the material can result in the cleavage of Sn—C bonds and liberation of the stabilizing R ligands which, in turn, allows for network formation and condensing of the irradiated regions and subsequent processing can further condense and/or densify the film. These synthesis techniques are described further in copending U.S. patent application Ser. No. 18/525,244 to Jilek et al. (hereinafter the '244 application), entitled “Direct Synthesis of OrganoTin Alkoxides,” incorporated herein by reference.

At the time of radiation patterning, hydrolysable ligands have generally been substantially removed to form the ultimate patterning composition from the precursor compositions. In general, organometallic radiation sensitive resists have been developed based on organo tin compositions, such as alkyltin oxide hydroxide, approximately represented by the formula R_{z}SnO_{(2-2/2-x/2)}(OH)ₓ, where 0<x<3, 0<z≤2, x+z≤4, and R is a hydrocarbyl or organo ligand forming a carbon bond with the tin atom. Particularly effective forms of these compositions are mono-organotin oxide hydroxide, in which z=1 or approximately =1 in the above formula, and the mono-organotin compositions are the focus herein. In particular, R can be an alkyl ligand with 1-31 carbon atoms with one or more carbon atoms optionally substituted with one of more heteroatom functional groups, such as groups containing O, N, Si, Ge, Sn, Te, and/or halogen atoms, or an alkyl, or a cycloalkyl further functionalized with a phenyl, or cyano group. In some embodiments, R can comprise ≤10 carbon atoms and can be, for example, methyl, ethyl, n-propyl, isopropyl, n-butyl, t-butyl, isobutyl, t-amyl, propenyl, butenyl, pentenyl, or isomers thereof. The R group can be a linear, branched, (i.e., secondary or tertiary at the metal-bonded carbon atom), or cyclic hydrocarbyl group. Each R group individually and generally has from 1 to 31 carbon atoms with 3 to 31 carbon atoms for the group with a secondary-bonded carbon atom and 4 to 31 carbon atoms for the group with a tertiary-bonded carbon atom, optionally with unsaturated or aromatic carbon bonds. Groups with unsaturated carbon bonds and no hetero atoms can be described as a branched or linear group with an overall stoichiometry of CₙH₂₍ₙ₋₁₎₊₃, n=1 to 31. In particular, branched alkyl (unsaturated) ligands can be desirable for some patterning compositions. The formation of the oxo-hydroxo coating material can comprise deposition of one or more tin composition(s) with hydrolysable bonds, such as RSnL₃, where L is a hydrolysable ligand, such as an alkoxide, a dialkyl amine, an acetylide, or other suitable hydrolysable ligand. The hydrolysable ligands can be hydrolyzed to form the oxo-hydroxo network during deposition of the coating and/or in the coating following deposition, i.e., completing the hydrolysis after deposition. Applicant has developed methodologies to efficiently and effectively form a wide range of patterning compositions with different R groups, optionally with various hetero atoms, with C—Sn bonds, as described further in published U.S. patent application 2022/00064192 to Edson et al., entitled “Methods to Produce Organotin Compositions With Convenient Ligand Providing Reactants,” incorporated herein by reference.

Processing of the organotin compositions to afford organotin oxo-hydroxo coatings (i.e., films) generally involves hydrolysis of the RSnL₃ composition(s) to afford the related organotin oxo-hydroxo composition(s). Hydrolysis can be performed prior to the deposition process to yield soluble organotin oxo-hydroxo species (i.e., clusters, oligomeric species, etc.) These soluble organotin oxo-hydroxo species can then be dissolved and/or dispersed into a suitable solvent to form an organotin photoresist solution that can then be used to form radiation-patternable organotin oxo-hydroxo coatings. Alternatively, the organotin compositions can be directly dissolved in a suitable solvent to form a photoresist solution that can then be used to form radiation-patternable organotin oxo-hydroxo coatings. The use of precursors with hydrolysable ligands has been found to be effective to afford solutions with good shelf lives and desirable coating properties. The organotin compositions can also be hydrolysed in-situ with water during the substrate coating process, such as during solution deposition or during vapor deposition. Various processing options are described further in the '684 and '618 patents referenced above.

For organotin photoresist compositions wherein the organotin compound(s) dissolved into a solvent for spin-coating, organotin trialkoxides (RSnL₃, L=OR′) can be desirable for use over other RSnL₃ compositions (e.g, organotin triamides, L=NR′₂). Some advantages to organotin trialkoxide compositions are, for example, the production of more benign side-products, e.g., alcohols, that are relatively innocuous compared to the production of gaseous products (e.g., amines) which may cause contamination, environmental health and safety (EHS) worries, and similar concerns within the wafer track and/or wafer fab. Organotin trialkoxides also possess appreciable vapor pressures and low melting points which makes them attractive compounds for use in vapor deposition methods to prepare radiation patternable coatings. In any case, selection of appropriate RSnL₃ compounds for formation of radiation patternable coatings can be informed by desirable processing conditions to afford formation of the desired radiation patternable organotin oxo hydroxo coatings wherein, prior to irradiation for patterning, Sn-L bonds are at least substantially cleaved and Sn—R bonds are at least substantially conserved.

Synthesis of organotin trialkoxide compounds have been previously described, such as in previous patent applications by Applicant. However, these reactions offering monoalkyltin trialkoxides as products generally involve conversion of an alkyl tin compound into an alkyl tin alkoxide rather than a direct synthesis. In other words, organotin trialkoxides have generally been synthesized through ligand replacement reactions. For example, organotin trialkoxides can be prepared from the corresponding organotin trichlorides by reaction with an alkali metal alkoxide, e.g., KOR′, NaOR′, and the like, according to the following reaction:

RSnCl₃+3MOR′→RSn(OR′)₃+3MCl

The potential product space for organotin trialkoxides is therefore limited by the access to and purity of the corresponding organotin trichloride. Organotin trichlorides are generally synthesized through the well-known Kocheskov Reaction where a tetraalkyl tin, R₄Sn, serves as a starting material for the synthesis of other organotin halides that are generated through redistribution reaction with SnCl₄. This reaction is known to be non-selective and highly sensitive to stoichiometry, and generally results in some distribution of off-target and undesired RₙSnCl₄₋ₙ products. For example, to synthesize RSnCl₃, a mixture of SnCl₄ and R₄Sn are reacted in a 3 to 1 ratio to target RSnCl₃ as the major product, but the reaction produces significant amounts of R₂SnCl₂ and R₃SnCl as side products. For semiconductor applications where high purity compounds are required for low defect processing and for commercial viability, one or more purification steps can be necessary to further purify and/or isolate the RSnCl₃ compound prior to its conversion to a trialkoxide, and the purification itself can be difficult. The synthetic methods described herein alleviate the need for a high-purity organotin trichloride starting material in the synthesis of an organotin trialkoxide.

Other methods of preparing organotin trialkoxides involve conversion of an organotin triamide to an organotin trialkoxide via the following reaction:

RSn(NR₂″)₃+3HOR′→RSn(OR′)₃+3HNR″₂

While this reaction is relatively straightforward, it is limited by factors such as it being exothermic so as to potentially lead to decomposition of the reactants and/or products, and high cost because of the necessity of first synthesizing the corresponding organotin triamide. While Applicant has previously described synthesis techniques for preparation of a wide variety of organotin triamides, there remains a desire to develop methods to directly synthesize organotin trialkoxides without the need to first obtain an organotin starting material with the desired R ligand identity. A direct synthesis of a target organotin trialkoxide, RSn(OR′)₃, is desirable and is described herein.

To perform high resolution radiation based patterning, it generally is desirable to have good radiation absorption, resist chemistry that provides a high contrast, and thermal stability to avoid decomposition of organo ligands unrelated to irradiation. Thermal stability tends to track with a need for a larger radiation dose to cleave the organo ligand, but increased radiation absorption can increase efficiency of the irradiation to compensate.

Fluorine atoms can be desirable to substitute for H atoms within the R ligands due to their higher EUV absorption. Additionally, the presence of F atoms within the R ligand can increase the hydrophobicity of the ligand, thus improving the developer contrast between irradiated and non-irradiated areas of the film. Organo ligands with fluorine substituents and trifluoromethyl groups are exemplified in the '244 application cited above, although no patterning results were presented in this application. Alkene groups are also exemplified in the '244 application, although again no patterning results are presented. The unsaturated alkenyl ligands are generally less thermally stable and less radiation stable than the corresponding saturated alkyl ligands, and the reactivity of the alkene groups may lead to undesirable non-radiation induced solubility changes in the unexposed regions of the film, such as cleavage of the ligand or other undesirable side reactions. Fluorination of the ligands can improve the thermal stability of the organotin compounds while also improving their EUV absorbance and, therefore, improved thermal stability and improved dose sensitivity can be realized. As radiolysis occurs in the irradiated regions and Sn—C bonds are cleaved, the stabilization against extended network formation is lost and the tin oxo hydroxo network within the irradiated regions can further densify and condense to form insoluble exposure products. Owing to the high thermal stability of the fluorinated ligands, the patterned coating can be heated at elevated temperatures to further promote densification of the irradiated material without concurrent decomposition of the unexposed organotin material and, thus, contrast between the irradiated and non-irradiated regions can be enhanced. Therefore, the inclusion of both fluorine substituted ligands and ligands with alkene groups can result in particularly desirable improvements in the patterning properties.

### Direct Synthesis of Organotin Trialkoxides:

Based on recently developed methods, monoalkyltin trialkoxides can be synthesized by one of two related synthesis methods. Both methods involve the reaction of an organohalide, such as an alkyl halide (RX), with a tin alkoxide compound to form a Sn—R bond. The tin alkoxide can be a di-tin tetraalkoxide (Sn₂(OR′)₄) or an alkali metal tin alkoxide, e.g., MSn(OR′)₃. In a first approach, the di-tin tertaalkoxides are reacted with an organohalide, generally in the presence of UV or monochromatic visible light, to form a monoalkyl tin trialkoxide, RSn(OR′)₃. In a second approach, the alkali metal tin trialkoxide is reacted with an organohalide to form the corresponding organo tin trialkoxide with low tin contaminant production, with the optional use of a catalyst.

The di-tin tetralkoxide (Sn₂(OR′)₄) and alkali metal tin alkoxide (MSn(OR′)₃) can be prepared using methods known in literature, for example, in an article by Veith et al. (hereinafter the Veith article), entitled “Alkoxistannate, II Tri(rerr-butoxi) alkalistannates(II): Synthesis and Structures,” Z. Naturforsch. 41b, 1071-1080 (1986), incorporated herein by reference. The Veith article does not suggest specific reactions using Sn₂(OR′)₄ or MSn(OtBu)₃ as further reactants to form alkyltin trialkoxides, e.g., RSn(OtBu)₃. The Veith article discloses the synthesis of MSn(OtBu)₃ using Sn₂(OtBu)₄. Veith also presents the structures. As exemplified herein, MSn(OtBu)₃ is synthesized in a two-step reaction from SnCl₂ and M(OtBu). After the first step, precipitated MCl (KCl) is removed, but no further purification is needed.

In a first approach, the synthesis of mono-organo tin trialkoxide is based on the following overall reaction:

MSn(OR′)₃+RX→RSn(OR′)₃

M is generally an alkali metal, such as Li, K, Na, Cs, or Rb and X is a halide ion, Cl, Br or I. R′ is generally an alkyl group with ≤10 carbon atoms, and OR′ can generally be selected for desirable properties of the product monoalkyltin trialkoxide, RSn(OR′)₃, such as stability, melting point, solubility, ease of purification, and so forth. In some embodiments, OR′ is tert-butoxide (OtBu). In some embodiments, OR′ is tert-amyloxide (OtAm). The RX compounds are selected to provide the desired alkyl ligand, R, for the mono-organotin products. The wide availability of RX compounds as reactants as well as the broad reactivity of the compounds in the corresponding reaction provides an ability to introduce a wide range of alkyl ligands into the product monoalkyl tin products. For the reactions described herein, primary and secondary R groups (i.e., R groups that have a 1° or 2° C. atom that forms the C—Sn bond) can be particularly effective at forming the desired RSn(OR′)₃ compositions. R ligands having unsaturated carbon bonds can also be prepared, as shown in the examples herein. X can generally be a halide chosen from I, Br, or Cl. It can be desirable for a catalyst to be present during the reaction to form the monoalkyltin trialkoxide. Some suitable examples of catalysts are tetrabutylammonium iodide, tetrabutylammonium bromide, tetrabutylammonium hexafluorophosphate, and tetraphenylphosphonium chloride.

The alkali tin alkoxide intermediate, MSn(OR′)₃, a bimetallic alkoxide of Sn(II), has been discovered to be a useful reagent for forming organotin trialkoxides, and can be prepared according to the following reaction:

Sn(OR′)₂+MOR′→MSn(OR′)₃

The alkali metal M can generally be chosen from Li, Na, K, Cs, or Rb. In some embodiments, M is K. In some embodiments, M is Li or Na. The MSn(OR′)₃ compound can be isolated, purified, and used as a solid reagent in the syntheses, and its preparation is included in the Examples herein. These compositions based on the five noted alkali metals have been studied and characterized in the Veith article cited above. When reacted with an alkylhalide at modest temperatures and conditions, an oxidative addition reaction can occur wherein an alkyl tin bond is formed with rapid formation of potassium halide to form RSn(OR′)₃. The potassium halide salt can be alternatively filtered away, and/or the RSn(OR′)₃ product can be purified and collected via distillation.

For some R groups, such as fluorinated organo groups, it has been discovered that the corresponding R^{F}Sn(OR′)₃ composition can be synthesized without the use of the alkali tin alkoxide composition, i.e., directly from Sn(OR) 2 ([Sn(OR′)₂]₂) in the presence of light, such as visible or UV light, according to the following reaction:

[Sn(OR′)₂]₂+R^{F}X→R^{F}Sn(OR′)₃+½Sn₂X₂(OR′)₂

[Sn(OR′)₂]₂ has been characterized. See Fjeldberg et al., “Chemistry of bulky alkoxides of bivalent germanium and tin; structures of gaseous [Sn(OBu)₂]₂ and crystalline Ge(OCBu)₂, Journal of the Chemical Society, Chemical Communications, Issue 14, 1985, 939-941, incorporated herein by reference (hereinafter Fjeldberg). As described herein, a new synthesis pathway is described using a reaction of SnCl₂ with MOR′, such as KOtBu.

In the Examples herein, synthesis of a fluorinated alkyltin trialkoxides, where R^{F}=trifluoroethyl (TFE, CF₃CH₂—) or R^{F}=3,4,4-trifluorobut-4-enyl (FBEN, CF₂═CFCH₂CH₂), and R′=tert-butyl, are described. While not wanting to be limited by theory, it is believed that the reaction with fluorinated alkyl groups involves a radical mechanism. The presence of the fluorine substituents seems to provide for UV activation, Notably, the reaction can be performed under UV irradiation without the presence of a bimetallic tin(II) alkoxide, while selective for monoalkylation of the tin. This reaction though results in a tin byproduct, SnX₂(OR′)₂ as a solid, which can be removed by filtration or other convenient method.

The reactions are generally performed in dry organic solvents under an oxygen free or depleted atmosphere, such as a nitrogen purged atmosphere. Solvents can be selected to result in the solubility of the various components as appropriate for the specific reactions. Due to interactions of the solvent with the metal ions, selection of solvents can be based at least in part on reaction rates in the selected solvents, which can be evaluated empirically. If different solvents are selected, they are generally miscible. Aprotic polar solvents are generally useful, such as ethers (for example, dimethyl ether, diethyl ether), tetrahydrofuran (THF), acetone, and mixtures thereof. For the alkylation steps in which the alkyl groups are bonded to the tin, nonpolar solvents are found to also be effective, such as alkanes (for example, hexane, pentane) and toluene. The solvents should generally be selected to be inert with respect to the reactants, intermediates and products. If multiple solvents are used, for example to introduce distinct reactants, the solvents should generally be miscible with respect to each other.

A catalyst comprising a halide can be present during the reaction of the bimetallic MSn(OR′)₃ compound and the alkylhalide RX compound. The catalyst can generally comprise a quaternary ammonium salt, such as tetrabutylammonium iodide, tetrabutylammonium bromide, and/or tetrabutylammonium hexafluorophosphate, and/or tetraphenylphosphonium chloride While the role of these catalysts is not completely clear, these compounds are known to act as phase transfer catalysts through helping inorganic compounds dissolve in organic solvents. Other phase transfer catalysts should be similarly useful in this context whether or not that function is directly exploited here, based on their common chemical properties.

The reactions using MSn(OR′)₃ as a starting material can generally be performed in a single pot without any intermediate steps, such as separation, purification, transfer, and the like.

The reactions described herein are highly selective towards formation of a monoalkyl tin trialkoxide compound, and the alkylhalide can generally be present as a reactant in a molar excess of the MSn(OR′)₃ composition. In some embodiments, the alkylhalide can be present up to about 2 mol. equivalents to the MSn(OR′)₃ compound, up to about 1.6 mol. equivalents to the MSn(OR′)₃ compound in other embodiments, up to about 1.3 mol. equivalents MSn(OR′)₃ compound in other embodiments, and up to about 1.1 mol. equivalents to the MSn(OR′)₃ compound in further embodiments. In some embodiments, the alkylhalide and the MSn(OR′)₃ compound can be present in roughly stoichiometric amounts. A person of ordinary skill in the art will recognize that additional ranges of reactant molar equivalents within the explicit ranges above are contemplated and are within the present disclosure.

In some embodiments, the reactions can generally be performed at temperatures less than about 100° C., less than about 80° C. in other embodiments, and less than 60° C. in further embodiments. In some embodiments, the reactions can be performed at room temperature. Generally, the reaction can be performed at temperatures from about −20° C. to about 100° C. In some embodiments, the reaction can be performed under UV irradiation. In embodiments wherein UV irradiation is performed during reaction, the reaction may or may not be heated. In some embodiments, the UV irradiation can be conducted with a wavelength of 365 nm. In some embodiments, the UV irradiation can be conducted with a wavelength on 254 nm, although other UV wavelengths are suitable. Generally, any reasonable light source can be selected, such as LEDs (coherent or noncoherent), lasers, plasmas, lamps, or other suitable light source. The reactions are generally stirred for the duration of the reaction. Efficacy of the reaction can be monitored by analyzing the reaction mixture via ¹H and/or ¹¹⁹Sn NMR to determine when the reaction has reached sufficient completion. In some embodiments, the reactions can be performed for no more than about 5 days, for no more than about 3 days in other embodiments, from about 2 minutes to about 1 day in other embodiments, and from about 5 minutes to about 1 hour in further embodiments. A person of ordinary skill in the art will recognize that additional ranges of time and temperature within the explicit ranges above are contemplated and are within the present disclosure. Desirable reaction times and temperatures can generally depend on the identity of the alkylhalide (RX). Reactivity of the alkylhalide generally follows in the order of X=I>Br>Cl, and in the order of the carbon forming the C—X bond as 1°>2°>>3°. Suitable reaction times and temperatures can be determined through routine experimentation.

Once the product is formed, the organotin trialkoxides can be purified. The purification depends on the nature of the product, but generally involves the separation of the desired product from byproducts and potentially any unreacted reagents. Purification can generally be achieved by methods known in the art. Suitable methods of purification can comprise filtration, recrystallization, extraction, distillation, combinations thereof, and the like. Filtration is typically performed on a crude product mixture to remove insoluble contaminants and/or byproducts, for example, metal halide salts such as KI, from the solution containing the desired product. Recrystallization methods can be useful to purify solid compounds by forming, via heating, a saturated solution that then is allowed to cool. Extraction techniques can comprise, for example, liquid-liquid extractions wherein two non-miscible solvents with different densities are used to separate the desired compounds based on their relative solubilities. Purification can also comprise removal of any volatile compounds including solvents from the product mixture by drying or exposure to vacuum. For products with significant vapor pressures, it can be desirable to purify the product through vacuum distillation or, if desired, fractional distillation designed to achieve high purity. See published U.S. patent application 2020/0241413 to Clark et al., entitled “Monoalkyl Tin Trialkoxides and/or Monoalkyl Tin Triamides With Low Metal Contamination and/or Particulate Contamination and Corresponding Methods,” incorporated herein by reference. Products can be also reacted to form derivatives, such as organotin compounds having other hydrolysable ligands (e.g., organotin triamides, organotin triacetylides, organotin acetamides, or organotin carboxylates) or organotin clusters, which can be further purified by the techniques above and other means known in the art.

### Precursor Compositions, Coatings, and Formation of Patternable Materials

A direct synthesis process for mono-organo tin trialkoxides is described in the following section, which can be effective for forming a range of precursor compositions. These precursors can be then used alone or in blends for forming coatings useful for radiation based patterning. Whether in a blend of precursors with different organo ligands or with a single type of precursor composition with a selected organo ligand, the precursors can provide fluorine groups and alkene groups. For solution coating, the one or more mono-organotin trialkoides can be mixed in a common solution with a solvent for delivery to a substrate surface. For vapor delivery, the precursors can be vaporized and delivered to a deposition chamber to form a coating on a substrate, though for blended coating compositions delivering the precursors as separate vapors can be desirable as more control over the deposition process can be achieved with separate vapor delivery for precursors with different organo or hydrolysable ligands.

It is generally desirable for photoresists to have a high thermal stability such that the material can be stable during lithographic processing prior to irradiation and development. Thermal processes are generally employed at various steps during the lithographic processes. For example, a post-apply bake (PAB) is typically performed after formation of the photoresist film to aid in the evaporation of solvent and to stabilize the film for further processing. Similarly, a post-exposure bake (PEB) is typically performed after radiation exposure of the photoresist film to promote reactions in the exposed regions and to enhance the solubility contrast between unexposed and exposed regions of the photoresist. While the irradiated materials are thermally responsive, the non-irradiated material should be stable at the PEB temperatures to avoid loss of contrast if significant amounts of ligands are lost from non-radiative processes. It is therefore desirable for organotin photoresists to endure elevated temperatures without significant decomposition, such as undesired rupture of the Sn—C bonds.

The photosensitivity of organotin photoresists generally involves radiation-induced cleavage of Sn—C bonds. The Sn—C bonds within the photoresist material generally hinder complete oxide hydroxide condensation of the photoresist film. Similarly, the presence of the organic groups bound to the Sn atoms via the Sn—C bonds generally imparts hydrophobicity to the unexposed organotin photoresist material. Therefore, the unexposed organotin photoresist is generally soluble in organic solvents. Exposure to radiation can cleave the Sn—C bonds, decreasing the hydrophobicity of the exposed material and enabling the exposed material to condense via the formation of Sn—O—Sn and Sn—OH bonds. Thus, patterning of the organotin resist can be achieved through selective decomposition of the radiation-sensitive Sn—C bonds and subsequent development based on the differential chemistry of the irradiated and non-irradiate regions.

While not wanting to be limited by theory, the thermal stability of the Sn—C bond can be correlated with the bond dissociation energy of the Sn—C bond. For example, Sn—C bonds of organic ligands with secondary and tertiary alpha carbons (i.e., the carbon directly bound to the Sn atom) generally require less energy to cleave than Sn—C bonds having primary alpha carbons. In other examples, functionalized organic ligands, such as those comprising unsaturated carbon-carbon bonds or heteroatoms, can also lower the bond dissociation energy of the Sn—C bonds and improve the radiation sensitivity of the organotin resist. In general, it is desirable for the Sn—C bonds of the organo ligands of the organotin photoresist to be readily cleaved by appropriate radiation such that high doses are not required to render a solubility change in the material. On the other hand, organo ligands forming Sn—C bonds with lower bond dissociation energies are also generally less thermally stable such that heating during lithographic processing can induce Sn—C cleavage in the non-irradiated areas which can reduce contrast and degrade patterning performance. Thus, it is found desirable to adjust the materials to increase radiation absorption without decreasing the thermal stability. The materials and blends described herein possess improved thermal stability which can allow for higher processing temperatures to densify the irradiated regions of the photoresist without significantly decomposing the Sn—C bonds in the unexposed regions. In this way, it is expected that a reduced amount of thermally induced Sn—C bond cleavage results absent radiation absorption while the increased radiation absorption promotes Sn—C bond cleavage at relatively lower doses of radiation. This combination of features can result in improved contrast. It has been found that blending of R ligands allows for adjustments to take greater advantage of these tradeoffs.

Fluorination and the use of alkenyl moieties within ligands of organotin resists can enhance the thermal stability and dose sensitivity of the photoresist. Electron-withdrawing groups, such as fluorine or fluorine containing groups, e.g., CF₃, within R groups. In some embodiments, the fluorine functionalities that are bound to olefinic carbons can also stabilize the alkene C═C bond and can reduce the reactivity of the ligand in the absence of radiation. Fluorinated ligands can also improve the radiation-sensitivity of the photoresist relative to non-fluorinated ligands because of the higher absorbance of extreme ultraviolet (EUV) radiation by fluorine atoms. The combination of fluorinated groups and alkenyl groups within one or a plurality of ligands described herein can show improved radiation sensitivity and improved thermal stability. In an appropriate balance, these can result in improved contrast.

In some embodiments, the fluorinated R ligands can comprise 1 to 15 carbon atoms, in further embodiments 2 to 10 carbon atoms, and 3 to 7 carbon atoms in other embodiments, and may have one, two or more —CF₃ groups, such as a trifluoroethyl (TFE) compound described in the Examples herein. In some embodiments, the R ligands can comprise a tertiary carbon having a C—F bond, e.g. —CFR′R″ wherein R′ and R″ are independently a hydrogen or an organo group having 1 to 10 carbon atoms, or a secondary carbon having a C—F bond, e.g., —CF₂R′, wherein R′ is an organo group having 1 to 10 carbon atoms. In other embodiments, alkyenyl groups can be fluorinated themselves.

In some embodiments, fluorinated alkenyl ligands can comprise compounds represented by the formula

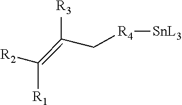

wherein R¹, R², and R³ are independently H, F, or an organo group with 1 to 8 carbon atoms, such as CF₃, or CH₃, wherein at least one of R¹, R², or R³ are fluorinated, e.g., F or CF₃, R⁴ is bond or a linear, cyclic, or branched alkyl group having from 1 to 10 carbon atoms, and wherein L is a hydrolysable ligand. In some embodiments, R¹, R², and R³ are all F. In some embodiments, R¹, R², and R³ are all CF₃. In some embodiments, R⁴ is —CH₂—. The hydrolysable ligand L can be any ligand with a hydrolysable bond to Sn such as alkoxide (OR′), amide (NR′₂), acetylide (CCR′), or chloride. In general, the identity of L can be chosen to facilitate formation of the associated organotin oxide hydroxide film and can be selected for suitable implementation of the deposition process. For example, alkoxides and amides can be desirable for use in deposition methods where rapid hydrolysis occurs during deposition, such as during spin-coating or vapor-deposition.

The organotin compounds having fluorinated alkenyl ligands, on the same ligand or separate ligands, can be blended into organotin photoresist solutions comprising one or more distinct organotin compounds. Blending two or more distinct organotin compounds can yield photoresists having improved stability and/or patterning performance relative to single-component photoresist compositions. The fluorinated alkenyl ligands can improve the photosensitivity of the blended composition relative to non-fluorinated alkenyl ligands while also providing improved thermal stability. The fluorinated alkenyl ligands can also impart hydrophobicity to the unexposed photoresist material which can aid in the development process wherein unexposed material is removed by an organic solvent.

With respect to blends of ligands, improved photosensitive precursor compositions can be present in a blended solution with one or more organotin compositions, such as RₙSnL₄₋ₙ and its hydrolysates, where R is chosen from the various moieties described in detail herein and elaborated on explicitly above. Generally, desirable ligands are mono-organo, so n=1 in the above formula. The blended solutions can be considered as (a¹R¹SnL¹₃, a²R²SnL²₃, . . . a^{m}R^{m}SnL^{m}₃), where for blends m≥2, such as 2, 3, 4, 5 or more than 5. While hydrolysable ligands Lm can be individually selected, they are generally substantially or completely hydrolyzed prior to patterning, so they can be selected to be identical or based on any other practical considerations with respect to effective and efficient precursor processing. Such blended solutions can be tuned for optimization of various performance considerations, such as solution stability, coating uniformity, and patterning performance. In some embodiments, the improved photosensitive composition can comprise at least about 1% by mol. Sn of a desired component in the blended solution, in further embodiments, at least about 5% by mol, in some embodiment at least about 10% by mol. Sn of the blended solution, in further embodiments from about 20% by mol to about 50% by mol. Sn of the blended solution. In blends of two precursors, the second precursor has a commensurate concentration in the solution, so for example, 99% paired with a 1% companion composition, and the like. If there are more than two components, these can be blended in any reasonable combination based on the parameters above, so for example, one precursor can be dominant with two or more minor components, all precursors can be present in non-majority amounts that are the same or differing by a relatively small fraction, such as a factor 2, or two or more can be in larger amounts of roughly the same order with a minor amount of one or more additional precursors. Sn of a specific desired component of the blended solution. A person of ordinary skill in the art will recognize that additional ranges of mol % of the improved photosensitive composition within the explicit ranges of the blended solution are contemplated and within the present disclosure. The hydrolysable ligands L can be hydrolyzed during deposition or following deposition, such as through hydrolysis with water vapor.

Of course in some embodiments, the overall precursor can comprise a single ligand R^{AF} with fluorine atoms and an alkene group. With respect to blends, a precursors with R^{AF1} ligands can be combined with other R^{AF2} ligands, R^{A} ligands, R^{F} ligands or R^{N} ligands, where R^{AF2} is a ligand comprising an alkene group and a fluorine atom with a different structure than R^{AF1}, R^{A} is a ligand comprising an alkene group, R^{F} is a ligand comprising one or more fluorine atoms, and R^{N} has no alkenyl or fluorine functionalities, and each of R^{AF2}, R^{A}, R^{F} and R^{N} independently optionally can have other hetero atoms and/or aromatic groups. As noted above, these organo ligands are found in compositions in the form RSnL^{m}₃. If these are in solution, as described further below, the hydrolysable ligands may exchange or partially exchange, but generally the R ligands are believed to not exchange. For vapor deposition, the precursors are generally neat liquids, and the absence of solvent generally maintains the compounds as purified. For vapor deposition of a precursor blend, the precursors can be delivered in the same proportions are described for the precursor solutions. For vapor deposition as with solution based deposition, two or more distinct RSnL₃ compounds having different R and/or L ligands can be used to form a final film that comprises a mixture of the RSn species. Generally, in the final film, any distinct RSn species are believed to be randomly distributed through the film in an interconnected oxo-hydroxo network, although this may or may not be true for sequential vapor deposition. Oxygen atoms can form bridging oxygen ligands upon hydrolysis. Within the integrated network, distinct R ligands can influence the collective behavior of the film.

Whether deposited by solution deposition or vapor deposition, hydrolysis of the hydrolysable ligands can result in formation of an oxo-hydroxo network represented by RSnOₓOH₃₋₂ₓ, where R can be one or a blend of organo ligands as described above. Generally, radiation exposure and patterning is performed with the hydrolyzed coating. Cleavage of RSn moieties are believed to allow for condensation of the material and further integration of the oxo-hydroxo network.

The substrate generally presents a surface onto which the coating material can be deposited, and it may comprise a plurality of layers in which the surface relates to an upper most layer. The substrate is not particularly limited and can comprise any reasonable material such as silicon, silica, other inorganic materials, such as ceramics, and polymer materials. Coating processing and patterning is described next.

### Coatings, Deposition, and Related Compositions:

The organotin precursor compositions described herein can be effectively used for radiation patterning, especially EUV patterning. The ability to have greater flexibility for ligand selection allows for further improvements in patterning results as well as designing ligands to be particularly effective for specific applications. In general, any suitable coating process can be used to deliver the precursor solution to a substrate. Suitable coating approaches can include, for example, solution deposition techniques such as spin coating, spray coating, dip coating, knife edge coating, printing, such as inkjet printing and screen printing, and the like. Many of the precursors are also suitable for vapor deposition onto a substrate as discussed in the '618 patent cited above. For some R ligand compositions and/or specific process considerations, vapor deposition may be useful for preparation of radiation sensitive coatings.

After preparation of the desired organotin precursor, the precursor can be dissolved in an appropriate solvent to prepare a precursor solution, such as an organic solvent, e.g., alcohols, aromatic and aliphatic hydrocarbons, esters or combinations thereof. In particular, suitable solvents include, for example, aromatic compounds (e.g., xylenes, toluene), ethers (anisole, tetrahydrofuran), esters (propylene glycol monomethyl ether acetate, ethyl acetate, ethyl lactate), alcohols (e.g., 4-methyl-2-pentanol, 1-butanol, methanol, isopropyl alcohol, 1-propanol), ketones (e.g., methyl ethyl ketone), mixtures thereof, and the like. In general, organic solvent selection can be influenced by solubility parameters, volatility, flammability, toxicity, viscosity and potential chemical interactions with other processing materials. After the components of the solution are dissolved and combined, the character of the species may change as a result of partial in-situ hydrolysis, hydration, and/or condensation.

The organotin precursors can be dissolved in the solvent at concentrations to afford concentrations of Sn suitable for forming coatings of appropriate thickness for processing. The concentrations of the species in the precursor solutions can be selected to achieve desired physical properties of the solution. In particular, lower concentrations overall can result in desirable properties of the solution for certain coating approaches, such as spin coating, that can achieve thinner coatings using reasonable coating parameters. It can be desirable to use thinner coatings to achieve ultrafine patterning as well as to reduce material costs. In general, the concentration can be selected to be appropriate for the selected coating approach. Coating properties are described further below. In general, tin concentrations comprise from about 0.005M to about 1.4M, in further embodiments from about 0.02 M to about 1.2 M, and in additional embodiments from about 0.1 M to about 1.0 M. A person of ordinary skill in the art will recognize that additional ranges of tin concentrations within the explicit ranges above are contemplated and are within the present disclosure.

In some embodiments, improved photosensitive precursor compositions can be present in a blended solution with one or more organotin compositions, such as RₙSnL₄₋ₙ and its hydrolysates, where R is chosen from the various moieties described in detail herein and elaborated on explicitly above. Such blended solutions can be tuned for optimization of various performance considerations, such as solution stability, coating uniformity, and patterning performance. In some embodiments, the improved photosensitive composition can comprise at least 1% by mol. Sn of a desired component in the blended solution, in further embodiments at least 10% by mol. Sn of the blended solution, in further embodiments at least 20% by mol. Sn of the blended solution, and in further embodiments at least 50% by mol. Sn of a specific desired component of the blended solution. Additional ranges of mol % of the improved photosensitive composition within the explicit ranges of the blended solution are contemplated and within the present disclosure.

Owing generally to their high vapor pressures, the organotin compositions described herein can be useful as precursors for forming coatings via vapor deposition. Vapor deposition methods generally include chemical vapor deposition (CVD), physical vapor deposition (PVD), atomic layer deposition (ALD), and modifications thereof. In a typical vapor deposition process, the organotin composition can be reacted with small molecule gas-phase reagents such as H₂O, O₂, H₂O₂, O₃, CH₃OH, HCOOH, CH₃COOH, and the like, which serve as O and H sources for production of radiation sensitive organotin oxide and oxide hydroxide coatings. Water vapor can be provided from ambient air, delivered in vapor form, or otherwise provided in a suitable liquid or vapor composition. While the vapor precursors can be delivered from separate reservoirs, once deposited and hydrolyzed, the R ligands can be distributed within a resulting oxo-hydroxo network. The distribution may or may not be homogenous depending on the vapor deposition strategy. Specific apparatuses for vapor deposition of radiation patternable organotin coatings has been described by Wu et. al in PCT Application #PCT/US2019/031618 entitled “Methods for Making EUV Patternable Hard Masks”, incorporated herein by reference. Production of radiation sensitive organotin coatings can generally be achieved by reacting the volatile organotin precursor RSnL₃ with a small gas-phase molecule. The reactions can include hydrolysis/condensation of the organotin precursor to hydrolyze the hydrolysable ligands while leaving the Sn—C bonds substantially intact.

With respect to an outline of a representative process for a radiation-based patterning, e.g., an extreme ultraviolet (EUV) lithographic process, photoresist material is deposited or coated as a thin film on a substrate, pre-exposure baked, exposed with a pattern of radiation to create a latent image, post-exposure baked, and then developed with a vapor based process or with a liquid, typically an organic solvent, to produce a developed pattern of the resist. Fewer steps can be used if desired, and additional steps can be used to remove residue to improve pattern fidelity.

The selected thickness of the radiation patternable coating can depend on the desired process. For use in single-patterning EUV lithography, coating thicknesses are generally chosen to yield patterns with low defectivity and reproducibility of the patterning. In some embodiments, suitable coating thickness can from between 1 nm and 100 nm, in further embodiments from about 2 nm to 50 nm, and in further embodiments from about 3 nm to 25 nm. Those of ordinary skill in the art will understand that additional ranges of coating thickness within the explicit ranges above are contemplated and are within the present disclosure.

Coating thickness for radiation patternable coatings prepared by vapor deposition techniques can generally be controlled through appropriate selection of reaction time or cycles of the process. The thickness of the radiation patternable coating can depend on the desired process. For use in single-patterning EUV lithography, coating thicknesses are generally chosen to yield patterns with low defectivity and reproducibility of the patterning. In some embodiments, suitable coating thickness can from between 1 nm and 100 nm, in further embodiments from about 2 nm to 50 nm, and in further embodiments from about 3 nm to 25 nm. Those of ordinary skill in the art will understand that additional ranges of coating thickness within the explicit ranges above are contemplated and are within the present disclosure.

The substrate generally presents a surface onto which the coating material can be deposited, and it may comprise a plurality of layers in which the surface relates to an upper most layer. After deposition and formation of the radiation patternable coating, further processing can be employed prior to exposure with radiation. In some embodiments, the coating can be heated from between 30° C. and 300° C., in further embodiments from between 50° C. and 200° C., and in further embodiments from between 80° C. and 150° C. The heating can be performed, in some embodiments for about 10 seconds to about 10 minutes, in further embodiments from about 30 seconds to about 5 minutes, and in further embodiments from about 45 seconds to about 2 minutes. A person of ordinary skill in the art will understand that additional ranges for temperatures and heating durations within the above explicit ranges are contemplated and are within the present disclosure.

### Patterning of the Compositions:

Radiation generally can be directed to the coated substrate through a mask or a radiation beam can be controllably scanned across the substrate. In general, the radiation can comprise electromagnetic radiation, an electron-beam (beta radiation), or other suitable radiation. In general, electromagnetic radiation can have a desired wavelength or range of wavelengths, such as visible radiation, ultraviolet radiation, or X-ray radiation. The resolution achievable for the radiation pattern is generally dependent on the radiation wavelength, and a higher resolution pattern generally can be achieved with shorter wavelength radiation. Thus, it can be desirable to use ultraviolet light, X-ray radiation, or an electron-beam to achieve particularly high-resolution patterns.

Following International Standard ISO 21348 (2007) incorporated herein by reference, ultraviolet light extends between wavelengths of greater than or equal to 100 nm and less than 400 30 nm. A krypton fluoride laser can be used as a source for 248 nm ultraviolet light. The ultraviolet range can be subdivided in several ways under accepted Standards, such as extreme ultraviolet (EUV) from greater than or equal 10 nm to less than 121 nm and far ultraviolet (FUV) from greater than or equal to 122 nm to less than 200 nm. A 193 nm line from an argon fluoride laser can be used as a radiation source in the FUV. EUV light at 13.5 nm has been used for lithography, and this light is generated from a Xe or Sn plasma source excited using high energy lasers or discharge pulses. Soft x-rays can be defined from greater than or equal to 0.1 nm to 5 less than 10 nm.

Based on the design of the coating material, there can be a large contrast of material properties between the irradiated regions that have condensed coating material and the unirradiated, coating material with substantially intact Sn—C bonds. For embodiments in which a post irradiation heat treatment is used, the post-irradiation heat treatment can be performed at temperatures from about 45° C. to about 250° C., in additional embodiments from about 50° C. to about 190° C. and in further embodiments from about 60° C. to about 175° C. The post exposure heating can generally be performed for at least about 0.1 minute, in further embodiments from about 0.5 minutes to about 30 minutes and in additional embodiments from about 0.75 minutes to about 10 minutes. A person of ordinary skill in the art will recognize that additional ranges of post-irradiation heating temperature and times within the explicit ranges above are contemplated and are within the present disclosure. This high contrast in material properties further facilitates the formation of high-resolution lines with smooth edges in the pattern following development as described in the following section.

For the negative tone imaging, the developer can be an organic solvent, such as the solvents used to form the precursor solutions. In general, developer selection can be influenced by solubility parameters with respect to the coating material, both irradiated and non-irradiated, as well as developer volatility, flammability, toxicity, viscosity and potential chemical interactions with other process material. In particular, suitable developers include, for example, alcohols (e.g., 4-methyl-2-pentanol, 1-butanol, isopropanol, 1-propanol, methanol), ethyl lactate, ethers (e.g., tetrahydrofuran, dioxane, anisole), ketones (pentanone, hexanone, 2-heptanone, octanone) and the like. The development can be performed for about 5 seconds to about 30 minutes, in further embodiments from about 8 seconds to about 15 minutes and in additional embodiments from about 10 seconds to about 10 minutes. A person of ordinary skill in the art will recognize that additional ranges within the explicit ranges above are contemplated and are within the present disclosure. In addition to the primary developer composition, the developer can comprise additional compositions to facilitate the development process. Suitable additives may include, for example, viscosity modifiers, solubilization aids, or other processing aides. If the optional additives are present, the developer can comprise no more than about 10 weight percent additive and in further embodiments no more than about 5 weight percent additive. A person of ordinary skill in the art will recognize that additional ranges of additive concentrations within the explicit ranges above are contemplated and are within the present disclosure. Desirable developer compositions are described in published U.S. patent application 2020/0326627 to Jiang et al., entitled “Organometallic Photoresist Developer Compositions and Processing Methods,” incorporated herein by reference.

With a weaker developer, e.g., diluted organic developer or compositions in which the coating has a lower development rate, a higher temperature development process can be used to increase the rate of the process. With a stronger developer, the temperature of the development process can be lower to reduce the rate and/or control the kinetics of the development. In general, the temperature of the development can be adjusted between the appropriate values consistent with the volatility of the solvents. Additionally, developer with dissolved coating material near the developer-coating interface can be dispersed with ultrasonication during development. The developer can be applied to the patterned coating material using any reasonable approach. For example, the developer can be sprayed onto the patterned coating material. Also, spin coating can be used. For automated processing, a puddle method can be used involving the pouring of the developer onto the coating material in a stationary format. If desired spin rinsing and/or drying can be used to complete the development process. Suitable rinsing solutions include, for example, ultrapure water, aqueous tetraalkyl ammonium hydroxide, methyl alcohol, ethyl alcohol, propyl alcohol and combinations thereof. After the image is developed, the coating material is disposed on the substrate as a pattern.

In some embodiments, a solventless (dry) development process may be conducted through the use of an appropriate thermal development or plasma development process, such as those described by Tan et. al in PCT Pat App. No: PCT/US2020/039615 entitled “Photoresist Development With Halide Chemistries”, incorporated herein by reference. For organotin photoresist coatings, dry development can be conducted through the use of halogen-containing plasmas and gases, for example HBr and BCl₃. See also, published U.S. patent application 2023/0408916 to de Schepper et al., entitled “Gas-Based Development of Organometallic Resist in an Oxidizing Halogen-Donating Environment,” incorporated herein by reference. In some cases, dry development may offer advantages over wet development such as reduced pattern collapse, deceased scum, and fine control over developer compositions, i.e. the plasma and/or etch gases.

After completion of the development step, the coating materials can be heat treated to further condense the material and to further dehydrate, densify, or remove residual developer from the material. This heat treatment can be particularly desirable for embodiments in which the oxide coating material is incorporated into the ultimate device, although it may be desirable to perform the heat treatment for some embodiments in which the coating material is used as a resist and ultimately removed if the stabilization of the coating material is desirable to facilitate further patterning. In particular, the bake of the patterned coating material can be performed under conditions in which the patterned coating material exhibits desired levels of etch selectivity. In some embodiments, the patterned coating material can be heated to a temperature from about 100° C. to about 600° C., in further embodiments from about 175° C. to about 500° C. and in additional embodiments from about 200° C. to about 400° C. The heating can be performed for at least about 1 minute, in other embodiment for about 2 minutes to about 1 hour, in further embodiments from about 2.5 minutes to about 25 minutes. The heating may be performed in air, vacuum, or an inert gas ambient, such as Ar or N₂. A person of ordinary skill in the art will recognize that additional ranges of temperatures and time for the heat treatment within the explicit ranges above are contemplated and are within the present disclosure. Likewise, non-thermal treatments, including blanket UV exposure, or exposure to an oxidizing plasma such as O₂ may also be employed for similar purposes.

### EXAMPLES

### Example 1. Synthesis of 1-but-3-enyltin tris(tert-butyl oxide) (MAL)

This example describes a method for the one-pot, direct synthesis of an unsaturated organo tin trialkoxide. The method is based on the following reaction. The reaction is performed with the addition of heat and a tetraalkyl (quaternary) ammonium salt as a catalyst.

KSn(OtBu)₃+(CH₃)(H)C═C(H)(CH₂Cl),→(CH₃)(H)C═C(H)(CH₂)Sn(OtBu)₃

KSn(OtBu)₃ was synthesized according to the procedure of the Veith article cited above. The KSn(OtBu)₃ product, 0.1 molar equivalents (referenced to 1 molar equivalent of tin) of tetrabutylammonium iodide ((n-Bu)₄N(I)) as a catalyst, and toluene were added to a reaction vessel under inert atmosphere and mixed to form a solution having a concentration of approximately 0.10 g KSn(OtBu)₃/ml toluene. The solution was mixed for at room temperature. Then 1.2 molar equivalents of 1-chloro-2-butene ((CH₃)(H)C═C(H)(CH₂Cl) (mixture of trans- and cis- and isomers, in an approximate ratio of 70:30) relative to the KSn(OtBu)₃ amount was added slowly with stirring. Then the reaction mixture was heated to 45° C. and stirred for 3 days. Afterwards, volatiles were removed under vacuum and the remaining residue was filtered over a bed of celite with pentane. The filtrate was pumped down and distilled to afford the product (CH₃)(H)C═C(H)(CH₂)Sn(OtBu)₃ (1-but-3-enyltin tris(tert-butyl oxide) or MAL) as a mixture of trans- and cis-isomers. The product was a clear yellow liquid.

The product was characterized by NMR. ¹H NMR (400 MHZ, neat) δ 5.70 (m, 2H), 2.41 (cis)+2.38 (trans) (m, 2H), 1.87 (m, 3H), 1.48 (cis)+1.49 (trans) (s, 27H) ppm; ¹¹⁹Sn NMR (149 MHZ, neat) δ −225 (trans), −227 (cis) ppm. The results indicate that the major isomeric species is trans-, with the ratio of the isomers in the MAL product retaining the ratio of the isomers in the 1-chloro-2-butene reagent. The results also indicate that there are no identified tin by-products in the conversion of KSn(OtBu)₃ to (CH₃)(H)C═C(H)(CH₂)Sn(OtBu)₃.

This example demonstrates a method for directly synthesizing an unsaturated organotin trialkoxide with high mono-organo specificity. This example also demonstrates that the method proceeds with both the trans- and cis-isomers of an olefinic halide reagent.

### Example 2. UV-Based Synthesis of 2,2,2-trifluoroethyltin tris(tert-butyl oxide) (TFE)

This example describes a method for the one-pot, direct synthesis of a fluorinated organo tin trialkoxide under UV light. The method is based on the following reaction.

Sn₂(OtBu)₄+CF₃CH₂I→CF₃CH₂Sn(OtBu)₃

Sn₂(OtBu)₄ was synthesized using the method of Veith. Sn₂(OtBu)₄, 1.3 molar equivalents (referenced to 1 molar equivalent of ditin reactant) of 2,2,2-trifluoroiodoethane (CF₃CH₂I), and pentane were added to a reaction vessel under inert atmosphere and mixed to form a solution having a concentration of approximately 0.33 g Sn₂(OtBu)₄/ml pentane. The solution was mixed at room temperature. Then, the solution was irradiated with ultraviolet light (40 W LED; 365 nm) overnight (approximately 15 hours). Afterwards, the reaction mixture was filtered over a bed of celite and the volatiles of the filtrate were removed under vacuum. The resulting filtrate was distilled to afford the final product CF₃CH₂Sn(OtBu)₃ (2,2,2-trifluoroethyltin tris(tert-butyl oxide) or TFE). The product was a clear yellow liquid and was characterized by NMR. ¹H NMR (400 MHZ, neat) δ 1.77 (m, 2H), 1.06 (s, 27H) ppm; ¹¹⁹Sn NMR (149 MHZ, neat) δ −231 (q) ppm; ¹⁹F NMR (neat) δ −53 (m) ppm. The NMR results indicate that there are no identified tin by-products in the synthesis of CF₃CH₂Sn(OtBu)₃.

This example demonstrates a photochemical method for directly synthesizing a fluorinated organotin trialkoxide with high mono-organo specificity.

### Example 3. LED-based Synthesis of 2,2,2-trifluoroethyltin tris(tert-butyl oxide) (TFE)

This example describes a photochemical method for the one-pot, direct synthesis of a fluorinated organo tin trialkoxide under visible (LED) light. The method is based on the following reaction.

KSn(OtBu)₃+CF₃CH₂I→CF₃CH₂Sn(OtBu)₃

KSn(OtBu)₃ was synthesized using the method of Veith. The KSn(OtBu)₃ product, 1.1 molar equivalents (referenced to 1 molar equivalent of tin) of 2,2,2-trifluoroiodoethane (CF₃CH₂I), and acetonitrile were added to a reaction vessel under inert atmosphere and mixed to form a solution having a concentration of approximately 0.25 g KSn(OtBu)₃/ml acetonitrile. The solution was mixed at room temperature. Then, while stirring, the solution was irradiated with visible light for 1 day. The visible light was provided via a 100 W LED and was either purple light (approximately 400 nm) or blue light (approximately 460 nm). The external temperature of the reaction vessel was maintained below 30° C. with the use of a fan. Afterwards, the reaction solvent was removed under reduced pressure and the remaining residue was filtered over a bed of celite with pentane. Volatiles of the filtrate were removed under vacuum and the resulting oil was distilled to afford the final product CF₃CH₂Sn(OtBu)₃ (2,2,2-trifluoroethyltin tris(tert-butyl oxide) or TFE). The product was a clear yellow liquid.

NMR spectra results of the product prepared with the purple light: ¹H NMR (400 MHz, neat) δ 1.57 (s, 27H), 2.27 (q, 2H) ppm; ¹¹⁹Sn NMR (149 MHZ, neat) δ −231 (q) ppm. The product prepared with the blue light showed indistinguishable results. The results indicate that there are no identified tin by-products in the conversion of KSn(OtBu)₃ to CF₃CH₂Sn(OtBu)₃.

Successful synthesis was also performed under green LED light, but not under ambient light.

This example demonstrates a photochemical method for directly synthesizing a fluorinated organotin trialkoxide with high mono-organo specificity and high yield. This example also demonstrates that the method is effective with visible light of various wavelengths. This example further demonstrates that the reaction to form the fluorinated trialkoxy product is photochemically driven.

### Example 4. Synthesis of 3,4,4-trifluorobut-4-enyltin tris(tert-butyl oxide) (FBEN)

This example describes a method for the one-pot, direct synthesis of a fluorinated alkenyl tin trialkoxide represented by Formula 1. The reaction is performed under UV light. The method is based on the following reaction.

Sn₂(OtBu)₄+CF₂CF(CH₂)₂I→(CF₂═CFCH₂CH₂Sn(OtBu)₃

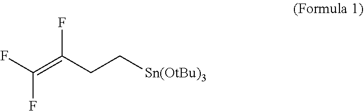

Sn₂(OtBu)₄, 1.1 molar equivalents (referenced to 1 molar equivalent of ditin reactant) of 4-iodo-1,1,2-trifluorobut-1-ene (CF₂CF(CH₂)₂I), and pentane were added to a reaction vessel under inert atmosphere and mixed to form a solution having a concentration of approximately 0.33 g Sn₂(OtBu)₄/ml pentane. The solution was mixed at room temperature. Then, the solution was irradiated with ultraviolet light (40 W LED; 365 nm) for 2 days. Afterwards, the reaction mixture was filtered over a bed of celite and the volatiles of the filtrate were removed under vacuum. The resulting filtrate was distilled to afford the final product CF₂CF(CH₂)₂Sn(OtBu)₃ (3,4,4-trifluorobut-4-enyltin tris(tert-butyl oxide) or FBEN). The product was a clear yellow liquid. The product was characterized by NMR. ¹H NMR (C₆D₆) δ 1.24 (m, 2H), 1.37 (s, 27H), 2.37 (m, 2H); ¹¹⁹Sn NMR (neat) δ −201 (d); ¹⁹F NMR (neat) δ −105.8 (dd), −123.3 (dd), −177.1 (dd).

This example demonstrates a photochemical method for directly synthesizing a fluorinated, unsaturated organotin trialkoxide with high mono-organo specificity.

### Example 5: Synthesis of but-4-enyltin tris(tert-butyl oxide) (BEN)

This example describes the synthesis of a non-fluorinated alkenyl tin trialkoxide represented by the formula ((CH₂═CHCH₂CH₂Sn(OtBu)₃) represented by Formula 2. The method is based on the following reaction. The reaction is performed with the addition of heat and a tetraalkyl (quaternary) ammonium salt as a catalyst.

KSn(OtBu)₃+CH₂═CH(CH₂)₂Br→CH₂═CHCH₂CH₂Sn(OtBu)₃

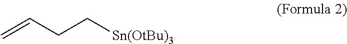

KSn(OtBu)₃ (prepared using methods or Veith cited above), 15 mol. % relative to moles Sn of tetrabutylammonium iodide ((n-Bu)₄N(I)) as a catalyst, and toluene were added to a reaction vessel under inert atmosphere and mixed to form a solution having a concentration of approximately 0.10 g KSn(OtBu)₃/ml toluene. The solution was mixed at room temperature. Then 1.1 molar equivalents of 4-bromobut-1-ene (CH₂═CH(CH₂)₂Br) relative to the KSn(OtBu)₃ amount was added slowly with stirring. Then the reaction mixture was heated to 80° C. and stirred. The reaction was monitored by NMR, and when all the 4-bromobut-1-ene and KSn(OBu)₃ was consumed the reaction was observed to stop. Thereafter, the solvent was removed under vacuum. The remaining residue was dissolved in pentane and filtered over a bed of celite, and the volatiles of the filtrate were removed under vacuum. The resulting filtrate was distilled at 70° C. by short path using a Pro-Pak® packed column to yield the final product CH₂═CHCH₂CH₂Sn(OtBu)₃ but-4-enyltin tris(tert-butyl oxide) or BEN). The product was a colorless liquid.

### Example 6: Thermal Stability of Fluorinated and Non-Fluorinated Alkenyl Ligands

This example describes the preparation of photoresist films using a fluorinated, unsaturated organotin precursor and a non-fluorinated derivative precursor and demonstrates that fluorination can provide for an increase in the thermal stability of photoresist films prepared with precursors having unsaturated ligands.

A first precursor solution (S1) was prepared by dissolving an appropriate amount of (CF₂═CFCH₂CH₂Sn(OtBu)₃ from Example 4 into 4-methyl-2-pentanol to form an organotin solution having an Sn concentration of 0.05 M [Sn]. A second precursor solution (S2) was prepared by dissolving an appropriate amount of (CH₂═CHCH₂CH₂Sn(OtBu)₃ from Example 5 into n-propanol to form an organotin solution also having an Sn concentration of 0.05 M [Sn]. Precursor solution S1 was spin-coated at 1500 rpm for 45 s onto undoped 4-inch Si wafers to produce a film sample (F1) with an average thickness of about 22 nm. Precursor solution S2 was spin-coated at 1500 rpm for 45 s onto undoped 6-inch Si wafers to produce a film sample (F2) with an average thickness of about 26 nm. Film thicknesses were measured via ellipsometry.

The coated wafers were then cleaved into approximately 1-inch chips. The chips coated with film sample F1 were either subjected to baking on a hotplate at temperatures of 75° C., 150° C., 180° C., 200° C., 230° C., 245° C., 260° C., or 290° C. for 2 minutes or no bake. The chips coated with film sample F2 were either subjected to baking on a hotplate at temperatures of 50° C., 100° C., 130° C., 160° C., 180° C., 200° C., 220° C., 240° C., 260° C., or 280° C. for 2 minutes or no bake.

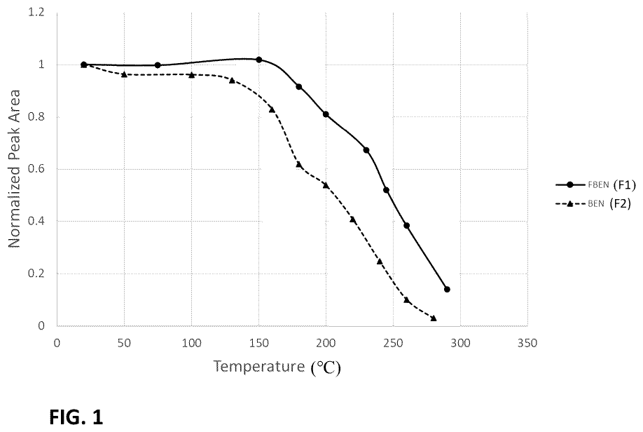

After completion of the selected baking step for the F1 and F2 film samples, the films were then analyzed via FTIR. For the non-fluorinated alkenyl ligand samples (F2), the peak area at 3075 cm-1, corresponding to the mid-point of the alkene C—H stretching region, was measured. For the fluorinated alkenyl ligand samples (F1), the peak area corresponding to the C—F stretching absorption was calculated as the sum of the measured peak areas at 1300 cm⁻¹, 1238 cm⁻¹, and 1166 cm⁻¹. The peak area for each of the baked films was then normalized to the peak area of the corresponding non-baked film. FIG. 1 shows the normalized peak area as a function of bake temperature for the film samples F1 (FBEN) and F2 (BEN). The plot's data points for the non-baked films are shown at 20° C., which the peak areas were normalized to. The thermal stability of each ligand type (fluorinated versus non-fluorinated) was assessed by inspection of the curves in FIG. 1. The FTIR results show a higher retention of the characteristic C—F absorptions in the F1 samples as compared to the characteristic C—H absorptions in the F2 samples across the temperature range studied. The fluorinated alkenyl ligands exhibited a higher thermal stability than the comparative non-fluorinated ligands. The results suggest that fluorinated, unsaturated organo ligands can be employed to enhance the high temperature stability of organotin precursor compositions.

This example demonstrated that an organotin film prepared with an organotin precursor having a fluorinated alkenyl ligand had a higher thermal stability than a comparative organotin film prepared with an organotin precursor having a non-fluorinated alkenyl ligand.

### Example 7: Patterning of Organotin Photoresists Prepared from Blends of Precursors

This example demonstrates that improvements to the radiation sensitivity of organotin photoresists can be achieved by blending a compound having a fluorinated alkenyl tin ligand into various organotin photoresist compositions.

A series of photoresist solutions were prepared from the organotin precursors listed in Table 1 and the solvents listed in Table 2. An appropriate amount of the selected organotin precursors was blended into the selected solvent according to Table 3 to form photoresist solutions having an Sn concentration of 0.05 M [Sn]. Blend A and Blend B are photoresist solutions formed from a blend of two organotin precursors (A and B) having non-fluorinated, saturated ligands: t-butyl and methyl, respectively. Precursor A was synthesized as described in U.S. Pat. No. 11,673,903 to Edson et al., incorporated herein by reference. Precursor B was synthesized as described in the '244 application, cited above, and precursors C and D were synthesized as described in the methods above. Blends C1-C3 are photoresist solutions formed from a blend of organotin precursor A, having non-fluorinated, saturated ligands, and organotin precursor C, having non-fluorinated, unsaturated ligands. Blends D1-D5 are photoresist solutions formed from a blend of two or three precursors, with at least one organotin precursor (A and/or B) having non-fluorinated, saturated ligands and one organotin precursor (D) having a ligand that is both fluorinated and unsaturated.

TABLE 1

| Organotin | |
|---|---|
| Precursor | Compound |
| A | tBuSn(OtAm)₃ |
| B | MeSn(OtAm)₃ |
| C | CH₂═CHCH₂CH₂Sn(OtBu)₃ |
| D | (CF₂═CFCH₂CH₂Sn(OtBu)₃ |

TABLE 2

| Solvent | Composition |
|---|---|
| Solvent 1 | 55 vol. % 1-pentanol |
| | 45 vol. % 1-propanol |
| Solvent 2 | 55 vol. % 4-methyl-2-pentanol |
| | 45 vol. % 1-propanol |

TABLE 3

| Photoresist | Precursor | |
|---|---|---|
| Solution | Composition | Solvent |
| Blend A | 80 mol % A | Solvent 1 |
| | 20 mol % B | |
| Blend D1 | 80 mol % A | Solvent 1 |
| | 20 mol % D | |
| Blend D2 | 75 mol % A | Solvent 1 |
| | 15 mol % B | |
| | 10 mol % D | |
| Blend D3 | 70 mol % A | Solvent 1 |
| | 20 mol % B | |
| | 10 mol % D | |
| Blend D4 | 65 mol % A | Solvent 1 |
| | 20 mol % B | |
| | 15 mol % D | |
| Blend D5 | 75 mol % A | Solvent 1 |
| | 20 mol % B | |
| | 5 mol % D | |
| Blend B | 80 mol % A | Solvent 2 |
| | 20 mol % B | |
| Blend C1 | 95 mol % A | Solvent 2 |
| | 5 mol % C | |
| Blend C2 | 90 mol % A | Solvent 2 |
| | 10 mol % C | |
| Blend C3 | 80 mol % A | Solvent 2 |
| | 20 mol % C | |

Photoresist film samples were prepared by spin-coating each photoresist solution listed in Table 3 onto 300 mm Si wafers coated with 10 nm spin-on-glass (SOG) to afford organotin photoresist film samples having an average thickness of approximately 24 nm. Line-space patterns having a target critical dimension (CD) of 16 nm on a 32 nm pitch (16p32) were produced from each photoresist film sample by exposing the samples to EUV radiation using an ASML NXE3400B exposure tool to create an array of patterns within fields on the wafer, with each field corresponding to the pattern printed at a specific dose. As is customary in the art, this type of exposure is referred to as a dose meander exposure. By exposing the same 16p32 pattern at different doses across each photoresist film sample, the dose required for printing the desired 16p32 pattern for a given photoresist film sample (i.e., the dose-to-size, DtS, for printing 16 nm lines on a 32 nm pitch) can be determined through inspection of each field after processing is complete. Following EUV exposure, each film was subjected to a post-exposure bake (PEB) at 160° C., 180° C., 190° C., or 200° C. for 60 s; developed with a solution of 5 wt. % acetic acid in PGMEA; and finally hard baked at 250° C. for 60 seconds to form a set of finished patterned wafers.

The finished patterned wafers were then analyzed via CDSEM and dose-to-size was determined for each wafer by inspection. Absolute doses corresponding to the desired 16p32 patterns were determined, and the percent change in DtS relative to the photoresist samples prepared from Blend A or Blend B (Control 1 and Control 2, respectively) were then calculated and tabulated as shown in Table 4. The EUV exposures for the photoresist samples prepared from Blend A (Control 1) and Blends D1 through D5 (Resists D1-D5) were carried out on different days than the EUV exposures for the photoresists prepared from Blend B (Control 2) and Blends C1 through C3 (Resists C1-C3). Each photoresist sample's DtS was normalized to the DtS of the associated photoresist control sample which was subjected to the same PEB temperature and patterned on the same day to remove day-to-day variations in absolute dose due to tool changes, environmental differences, and other potential sources of variability.

TABLE 4

| | | Change in | Change in | Change in | Change in |
|---|---|---|---|---|---|
| Photo- | Photo- | DtS for | DtS for | DtS for | DtS for |
| resist | resist | 160° C. | 180° C. | 190° C. | 200° C. |
| Sample | Solution | PEB, % | PEB, % | PEB, % | PEB, % |
| Control 1 | Blend A | n/a | n/a | n/a | n/a |
| Resist D1 | Blend D1 | −22.89% | −39.03 | ** | ** |
| Resist D2 | Blend D2 | −16.64 | −28.87 | −36.05 | ** |
| Resist D3 | Blend D3 | −21.46 | −32.90 | −43.30 | ** |
| Resist D4 | Blend D4 | −31.21 | −46.13 | ** | ** |
| Resist D5 | Blend D5 | −11.31 | −17.26 | −22.83 | −30.57 |
| Control 2 | Blend B | n/a | n/a | n/a | n/a |
| Resist C1 | Blend C1 | 17.89 | 32.99 | 30.00 | 44.11 |
| Resist C2 | Blend C2 | 11.45 | 20.69 | 16.58 | 28.76 |
| Resist C3 | Blend C3 | −0.05 | 5.96 | −10.19 | −5.49 |

**indicates a DtS that was too low to measure (<30 mJ/cm²)

Resists C1-C3 were formed from precursor solutions having a blend of tBuSn(OtAm)₃ and either 5 mole % (Resist C1), 10 mole % (Resist C2), or 20 mole % (Resist C3) of a precursor with a non-fluorinated alkenyl ligand (CH₂═CHCH₂CH₂Sn(OtBu)₃). Referring to Table 4, Resists C1 and C2 showed an increase in DtS over the Control 2 resist (formed from a precursor solution having a blend of tBuSn(OtAm)₃ and 20 mole % tBuSn(OtAm)₃) at all of the PEB temperatures tested. The increase in DtS was higher for Resist C1 than for Resist C2 at all of the temperatures tested and ranged from 17.89% to 44.11%. The change in DtS generally increased with increasing PEB temperature. Resist C3 showed a modest decrease in DtS at PEB temperatures of 160° C., 190° C., and 200° C. relative to the Control 2 resist. At a PEB temperature of 180° C., Resist C3 shows a modest increase in DtS relative to Control 2. The results for Resist C3 provide a direct comparison of the resist performance when the same weight percent of an unsaturated precursor is used in place of the saturated precursor MeSn(OtAm)₃. The results for Resists C1-C3 show the effect on DtS by incorporating various weight percentages of an unsaturated precursor into a photoresist film.

In contrast to Resist C1, Resist D1 (prepared from 20 mole % of a fluorinated alkenyl tin compound and 80 mole % tBuSn(OtAm)₃) showed a significant decrease in DtS relative to its control resist (Control 1) at each of the PEB temperatures tested. A 23% and a 39% decrease in DtS was observed for Resist D1 at PEB temperatures of 160° C. and 180° C., respectively. This result was indicative of a significant photosensitivity improvement for binary blends of (CF₂═CFCH₂CH₂Sn(OtBu)₃ and tBuSn(OtAm)₃. At the two highest PEB temperatures tested (190° C. and 200° C.), the decrease in the DtS relative to the control was even more pronounced such that every pattern was overdosed and the dose-to-size values could not be captured (indicated by the ** designation in Table 4) even at the lowest doses measured (30 mJ/cm²). The Resist D1 results show that substituting MeSn(OtAm)₃ with a fluorinated alkenyl tin compound in a photoresist blend with tBuSn(OtAm)₃ significantly improved the DtS.

Resists D2-D5 were prepared from a ternary blend of organotin compositions: (CF₂═CFCH₂CH₂Sn(OtBu)₃, MeSn(OtAm)₃, and tBuSn(OtAm)₃. Each of these ternary blended resists showed a decrease in the DtS at each PEB temperature tested. The ternary blended resists prepared with higher relative amounts of the fluorinated alkenyl tin compound showed correspondingly greater reductions in DtS. Resist D4 (prepared with 15 mol. % of organotin precursor D) showed a greater reduction in DtS than Resists D3 and D2 (prepared with 10 mol. % of organotin precursor D) and Resist D5 (prepared with 5 mol. % of organotin precursor D) at each PEB temperature tested. At a PEB temperature of 200° C. the DtS for ternary blended Resists D2 through D5 were too low to be captured on the wafer. Resist D4 (15% of organotin precursor D) also showed a greater reduction in the DtS than Resist D1 (20% of organotin precursor D). The Resist D2-D5 results show that the dose sensitivity improvements provided by the addition of a fluorinated, alkenyl tin compound may be further improved by incorporation into a blend with two or more other organotin compounds.

The results of this study show that blending of an organotin compound having a fluorinated alkenyl ligand into organotin photoresist compositions can significantly increase the dose sensitivity of the photoresist.

### Further Inventive Concepts

1. A fluorinated organometallic compound represented by the formula R^{UF}Sn(OR′)₃, wherein R^{UF} is an organo group with 1 to 31 carbon atoms with at least one C═C bond and at least one fluorine atom bonded to a carbon, with the organo group forming a C—Sn bond, wherein R′ is an organo group with 1 to 10 carbon atoms.

2. The fluorinated organometallic compound of inventive concept 1, wherein R^{UF} is a fluorinated alkenyl ligand.

3. The fluorinated organometallic compound of inventive concept 1 wherein R^{UF} comprises at least one carbon atom that has both a C═C bond and a C—F bond.

4. The fluorinated organometallic compound of inventive concept 1, wherein R^{UF} consists essentially of C, H, and F atoms.

5. The fluorinated organometallic compound of inventive concept 2, wherein the fluorinated alkenyl ligand comprises at least one carbon atom that forms both a C═C bond and one or more C—F bonds, wherein R′ is a branched or linear group with an overall stoichiometry of CₙH₂₍ₙ₋₁₎₊₃, n=1 to 10.

6. The fluorinated organometallic compound of inventive concept 1 wherein R^{UF} is selected from the group consisting of a fluorinated alkenyl ligand, a fluorinated aryl ligand, and a fluorinated alkynl ligand.

7. The fluorinated organometallic compound of inventive concept 1 wherein R′ is a linear, branched or cyclic group with a stoichiometry of CₙH₂₍ₙ₋₁₎₊₃, n=1 to 10.

8. The fluorinated organometallic compound of inventive concept 1 wherein R′ comprises a methyl, an ethyl, an n-propyl, an iso-propyl, an n-butyl, an iso-butyl, a tert-butyl, or a tert-amyl group, or combinations thereof.

9. The fluorinated organometallic compound of inventive concept 1 wherein R^{UF}Sn(OR′)₃ is 3,4,4-trifluorobut-4-enyltin tris(tert-butyl oxide).

10. The fluorinated organometallic compound of inventive concept 1 wherein the R^{UF}—Sn bond is more thermally stable than an equivalent R^{NF}—Sn bond wherein the R^{NF} ligand has a hydrogen atom in place of each fluorine atom but is otherwise identical to R^{UF}.

11. A blend comprising the fluorinated organometallic compound of inventive concept 1 and a compound represented by the formula R²SnL′₃, where R² is an organo group with 1 to 20 carbon atoms and is different from R^{UF} and L′ is a hydrolysable ligand.

12. A photoresist composition comprising an organic solvent and the fluorinated organometallic compound of inventive concept 1.

13. The photoresist composition of inventive concept 12 wherein the organic solvent comprises an alcohol or a combination thereof.

14. The photoresist composition of inventive concept 12 wherein the organic solvent comprises a primary alcohol.

15. The photoresist composition according to inventive concept 12 wherein R^{UF} comprises at least one carbon atom that has both a C═C bond and a C—F bond.

16. The photoresist composition according to inventive concept 12 wherein R^{UF} is a fluorinated alkenyl ligand.

17. A method for synthesizing a fluorinated organometallic compound represented by the formula R^{UF}Sn(OR′)₃, where R^{UF} is an organo group with 1 to 31 carbon atoms with unsaturated C—C bonds and at least one fluorine atom bonded to a carbon, wherein R^{UF} forms a C—Sn bond and R′ is an organo group with 1 to 10 carbon atoms, the method comprising:
reacting R^{UF}X with Sn₂(OR′)₄ or MSn(OR′)₃ under visible or ultraviolet light where X is Cl, Br or I.

18. The method of inventive concept 17 wherein R^{UF} comprises a C═C group.

19. The method of inventive concept 17 wherein R^{UF} comprises 3 to 12 carbon atoms.

20. The method of inventive concept 17 wherein R^{UF} comprises an alkenyl or an aryl group.

21. The method of inventive concept 17 wherein X is Br or I and, if MSn(OR′)₃ is used, M is K.

22. The method of inventive concept 17 wherein reacting is performed for less than about 2 days.

23. The method of inventive concept 17 wherein reacting is performed at a temperature from about −20° C. to about 100° C.

24. The method of inventive concept 17 wherein reacting is performed at room temperature.

25. The method of inventive concept 17 wherein the visible or ultraviolet light is provided by a selected light source.

26. The method of inventive concept 17 further comprising purifying the R^{UF}Sn(OR′)₃ product using distillation.

27. The method of inventive concept 17 wherein R^{UF}X is reacted with Sn₂(OR′)₄.

28. The method of inventive concept 27 wherein R^{UF}X is CF₂CF(CH₂)₂I and R′ is a t-butyl group.

29. A composition comprising R^{B}SnO_{(3/2-x/2)}(OH)ₓ, where 0<x<3 and R^{B} represents an organo group or a blend of ligands each being an organo group, where each organo group independently has 1 to 31 carbon atoms, collectively the organo group(s) have at least one carbon atom that has a C═C bond and at least one carbon atom has a C—F bond, and each organo group forming a C—Sn bond, the composition comprising an oxo-hydroxo network.

30. The composition of inventive concept 29 wherein R^{B} comprises a blend of ligands, wherein each ligand is, within the collective constraints, a fluorinated ligand free of unsaturated carbon-carbon bonds, a fluorinated alkenyl ligand, a fluorinated aryl ligand, a non-fluorinated ligand free of unsaturated carbon-carbon bonds, a non-fluorinated alkenyl ligand, a non-fluorinated aryl ligand, or a combination thereof.

31. The composition of inventive concept 29 wherein R^{B} comprises a ligand having at one carbon atom forming both a C═C bond and a C—F bond.

32. The composition of inventive concept 31 wherein the ligand forms at least 95% of the total C—Sn bonds of the composition.

33. The composition of inventive concept 29 wherein R^{B} represents a blend of ligands each independently having an organo group with 1 to 31 carbon atoms that are different from each other and collectively comprise at least one carbon atom that has an unsaturated bond and at least one carbon atom that has a C—F bond, with each organo group forming a C—Sn bond, wherein each ligand forms at least about 1% of the total C—Sn bonds in the composition.

34. The composition of inventive concept 33 wherein one ligand comprises 3,4,4-trifluorobut-4-enyl bound to tin and a second ligand comprises but-4-enyl bound to tin.

35. The composition of inventive concept 33 wherein a first ligand comprises 3,4,4-trifluorobut-4-enyl bound to tin and a second ligand comprises t-butyl bound to tin.

36. The composition of inventive concept 33 wherein a first ligand comprises 3,4,4-trifluorobut-4-enyl bound to tin, a second ligand comprises t-butyl bound to tin, and a third ligand comprises methyl bound to tin.

37. A coated substrate comprising a substrate with a surface and the composition of inventive concept 29 on the surface of the substrate.

38. The coated substrate of inventive concept 37 wherein the coated substrate comprises a silicon wafer.

39. A method for forming a patterning composition on a substrate surface, the method comprising:
coating a solution onto the substrate surface, wherein the solution comprises a solvent and a dissolved blend of R¹SnL¹₃ and R²SnL²₃, where R¹ and R² are independently an organo group with 1 to 31 carbon atoms that are different from each other and collectively comprise at least one unsaturated carbon-carbon bond and at least 1 fluorine atom bound to a carbon atom, with the organo group forming a C—Sn bond, wherein R¹SnL¹₃ and R²SnL²₃ each comprise at least about 1% of the total Sn atoms in the composition and L¹ and L² are independently selected hydrolysable ligands; and
removing the solvent to form a coating comprising R^{B}SnO_{(3/2-x/2)}(OH)ₓ, where 0<x<3 and R^{B} is a blend of R¹ and R² ligands.

40. The method of inventive concept 39 wherein the solvent comprises an alcohol.

41. The method of inventive concept 39 wherein R¹ comprises a fluorinated ligand free of unsaturated carbon-carbon bonds, a fluorinated alkenyl ligand, a fluorinated alkynyl ligand, a fluorinated aryl ligand, or a combination thereof.

42. The method of inventive concept 39 wherein R² comprises a non-fluorinated ligand free of unsaturated carbon-carbon bonds, a non-fluorinated alkenyl ligand, a non-fluorinated alkynyl ligand, a non-fluorinated aryl ligand, or a combination thereof.

43. A method for forming a radiation-patternable coating on a substrate surface, the method comprising:
simultaneously or sequentially reacting organotin precursor with a counter-reactant to form a patternable organometallic composition on the surface of the substrate, wherein the organotin precursor and the counter-reactant are supplied as vapors, and wherein the organotin precursor vapors comprise R¹SnL¹₃ and R²SnL²₃, where R¹ and R² are independently an organo group with 1 to 31 carbon atoms that are different from each other and collectively comprise at least one unsaturated carbon-carbon bond and at least 1 fluorine atom bound to a carbon atom, with the organo group forming a C—Sn bond, wherein R¹SnL¹₃ and R²SnL²₃ each comprise at least about 1% of the total Sn atoms in the composition and L¹ and L² are independently selected hydrolysable ligands,
wherein the counter-reactant comprises water, molecular oxygen, and/or other oxygen donating compound; and forming a radiation-patternable coating on the substrate surface wherein the radiation-patternable coating comprises R^{B}SnO_{(3/2-x/2)}(OH)ₓ, where 0<x<3 and R^{B} is a blend of R¹ and R² ligands.

44. The method of inventive concept 43 wherein R¹ comprises a fluorinated ligand free of unsaturated carbon-carbon bonds, a fluorinated alkenyl ligand, a fluorinated aryl ligand, or a combination thereof.

45. The method of inventive concept 43 wherein R² comprises a non-fluorinated ligand free of unsaturated carbon-carbon bonds, a non-fluorinated alkenyl ligand, a non-fluorinated aryl ligand, or a combination thereof.

46. The method of inventive concept 43 wherein the organotin precursor vapors are formed from two independent reservoirs for R¹SnL¹₃ and R²SnL²₃.

47. The method of inventive concept 43 wherein the reacting is performed with exposure to an atmosphere comprising water vapor and molecular oxygen.

48. A composition comprising a blend of R¹SnL¹₃ and R²SnL²₃, wherein R¹ and R² are independently an organo group comprising from 1 to 31 carbon atoms, that are different from each other and collectively comprise at least one fluorinated group and a C═C bond, and each forms a C—Sn bond, wherein R^{F}SnL¹₃ comprises at least about 1% of the total Sn atoms in the composition, and wherein L¹ and L² are independently selected hydrolysable ligands.

49. The composition of inventive concept 48 wherein R² is an organo group comprising from 1 to 31 carbon atoms without any C—F bonds and forms a C—Sn bond.

50. The composition of inventive concept 48 wherein the fluorine groups(s) provide thermal stabilization of the R^{a}—Sn bond, a=1 or 2, relative to an equivalent R^{NF}—Sn bond where the R^{NF} ligand has a hydrogen atom in place of each fluorine atom but is otherwise identical to R^{a}.

51. The composition of inventive concept 48 wherein R¹ and R² are independently selected from the group consisting of a fluorinated ligand free of unsaturated carbon-carbon bonds, a fluorinated ligand comprising a C═C bond, a fluorinated ligand comprising an aromatic group, a non-fluorinated ligand free of unsaturated carbon-carbon bonds, a non-fluorinated ligand comprising a C═C bond, and a non-fluorinated ligand comprising an aromatic group.

52. The composition of inventive concept 48 wherein R¹ comprises a fluorinated alkenyl ligand and R² comprises a non-fluorinated ligand free of unsaturated carbon bonds.

53. The composition of inventive concept 48 wherein R¹ comprises a fluorinated ligand free of unsaturated carbon-carbon bonds and R² comprises a non-fluorinated alkenyl ligand.

54. The composition of inventive concept 48 wherein R¹ and R² collectively comprise at least one carbon atom that has more than one C—F bond.

55. The composition of inventive concept 48 wherein R¹ comprises at least one carbon atom that has a C═C bond and at least one carbon atom that has a C—F bond. 56. The composition of inventive concept 55 wherein R² comprises methyl, n-propyl, iso-propyl, n-butyl, t-butyl, t-amyl, propenyl, butenyl, pentenyl, or a combination thereof.

57. The composition of inventive concept 48 wherein R¹ comprises at least one carbon atom that has both a C═C bond and a C—F bond.

58. The composition of inventive concept 48 wherein R¹SnL¹₃ and R²SnL²₃ each comprise at least about 5% of the total Sn atoms in the composition.

59. The composition of inventive concept 48 wherein L¹ and/or L² are a dialkylamide, an alkylsilylamide, an alkoxide, an alkylacetylide, or a combination thereof.

60. The composition of inventive concept 48 wherein L¹ and/or L² are an alkoxide.

61. The composition of inventive concept 48 wherein R¹SnL²₃ comprises 3,4,4-trifluorobut-4-enyltin tris(tert-butyl oxide) and R²SnL²₃ comprises but-4-enyltin tris(tert-butyl oxide).

62. The composition of inventive concept 48 wherein R¹SnL²₃ comprises 3,4,4-trifluorobut-4-enyltin tris(tert-butyl oxide) and R²SnL²₃ comprises t-butyltin tris(tert-amyl oxide).

63. The composition of inventive concept 48 wherein the blend further comprises R³SnL³₃, wherein R³ is independently an organo group with 1 to 31 carbon atoms that is different from R¹ and R² and forming a C—Sn bond, wherein R³SnL³₃ comprises at least about 1% of the total Sn atoms in the composition and L³ is an independently selected hydrolysable ligand.

64. The composition of inventive concept 63 wherein R³ is selected from the group consisting of a fluorinated ligand free of unsaturated carbon-carbon bonds, a fluorinated ligand comprising a C═C bond, a fluorinated ligand comprising an aromatic group, a non-fluorinated ligand free of unsaturated carbon-carbon bonds, a non-fluorinated ligand comprising a C═C bond, and a non-fluorinated ligand comprising an aromatic group.

65. The composition of inventive concept 63 wherein L¹, L², and/or L³ are a dialkylamide, an alkylsilylamide, an alkoxide, an alkylacetylide, or a combination thereof.

66. The composition of inventive concept 63 wherein L¹, L² and/or L³ are an alkoxide.

67. A photoresist composition comprising an organic solvent and the composition of inventive concept 48.

68. The photoresist composition of inventive concept 67 wherein the organic solvent comprises an alcohol.

69. The photoresist composition of inventive concept 67 wherein the organic solvent comprises a primary alcohol.

70. A fluorinated organometallic compound represented by the formula R^{UF}SnL₃, wherein R^{UF} is an organo group having from 1 to 31 carbon atoms with at least one carbon atom that forms both a C═C bond and a C—F bond, and wherein R^{UF} forms a C—Sn bond, and wherein L is a hydrolysable ligand.

71. The fluorinated organometallic compound according to inventive concept 70 wherein R^{UF} comprises a fluorinated alkenyl group having the formula R¹R²C═CR³R⁴ wherein R¹, R², and R³ are independently F or CF₃, and wherein R⁴ is an alkyl group having from 1 to 15 carbon atoms and forming an Sn—C bond.

72. The fluorinated organometallic compound according to inventive concept 71 wherein R⁴ is a branched or linear group with a stoichiometry of CₙH₂₍ₙ₋₁₎₊₃, n=1 to 5.

73. The fluorinated organometallic compound according to inventive concept 70 wherein L is a dialkylamide, an alkylsilylamide, an alkoxide, an alkylacetylide, or a combination thereof.

74. The fluorinated organometallic compound according to inventive concept 70 wherein L is a dialkylamide, an alkylsilylamide, an alkylacetylide, or a combination thereof.

75. The fluorinated organometallic compound according to inventive concept 70 wherein R^{UF} consists essentially of C, H, and F atoms.

76. A fluorinated organotin composition comprising an R^{UF}—Sn bond, wherein R^{UF} is an organo group having from 1 to 31 carbon atoms with at least one carbon atom that forms both a C═C bond and a C—F bond, and the R^{UF}—Sn bond comprises a C—Sn bond.

77. The fluorinated organotin composition of inventive concept 76 comprising an oxo-hydroxo network.

78. The fluorinated organotin composition of inventive concept 76 comprising a compound represented by the formula R^{UF}—SnL³, wherein L is is a dialkylamide, an alkylsilylamide, an alkoxide, an alkylacetylide, hydroxide, oxo or a combination thereof. 79. The fluorinated organotin composition of any one of inventive concepts 76-78 wherein the C—Sn bond can be cleaved by EUV light.

The embodiments above are intended to be illustrative and not limiting. Additional embodiments are within the claims. In addition, although the present invention has been described with reference to particular embodiments, those skilled in the art will recognize that changes can be made in form and detail without departing from the spirit and scope of the invention. Any incorporation by reference of documents above is limited such that no subject matter is incorporated that is contrary to the explicit disclosure herein. To the extent that specific structures, compositions and/or processes are described herein with components, elements, ingredients or other partitions, it is to be understand that the disclosure herein covers the specific embodiments, embodiments comprising the specific components, elements, ingredients, other partitions or combinations thereof as well as embodiments consisting essentially of such specific components, ingredients or other partitions or combinations thereof that can include additional features that do not change the fundamental nature of the subject matter, as suggested in the discussion, unless otherwise specifically indicated. The use of the term “about” herein refers to expected uncertainties in the associated values as would be understood in the particular context by a person of ordinary skill in the art.

What is claimed is:

1. A composition comprising a blend of R¹SnL¹₃ and R²SnL²₃, where R¹ and R² are independently an organo group with 1 to 31 carbon atoms that are different from each other and collectively comprise at least one carbon atom that has at least one unsaturated carbon-carbon bond and at least one carbon atom that has a C—F bond, with each organo group forming a C—Sn bond, wherein R¹SnL¹₃ and R¹SnL¹₃ each comprise at least about 1% of the total Sn atoms in the composition and L¹ and L² are independently selected hydrolysable ligands.

2. The composition of claim 1 wherein the fluorine atom(s) provide thermal stabilization of an R^{a}—Sn bond, a=1 or 2, wherein R^{a} comprises a C—F bond, wherein the stabilization is relative to an equivalent R^{NF}—Sn bond where the R^{NF} ligand has a hydrogen atom in place of each fluorine atom but is otherwise identical to R^{a}.

3. The composition of claim 1 wherein R¹ and R² are independently selected from the group consisting of a fluorinated ligand free of unsaturated carbon-carbon bonds, a fluorinated ligand comprising a C═C bond, a fluorinated ligand comprising an aromatic group, a non-fluorinated ligand free of unsaturated carbon-carbon bonds, a non-fluorinated ligand comprising a C═C bond, and a non-fluorinated ligand comprising an aromatic group.

4. The composition of claim 1 wherein R¹ comprises a fluorinated alkenyl ligand and R² comprises a non-fluorinated ligand free of unsaturated carbon bonds.

5. The composition of claim 1 wherein R¹ comprises a fluorinated ligand free of unsaturated carbon-carbon bonds and R² comprises a non-fluorinated alkenyl ligand.

6. The composition of claim 1 wherein R¹ and R² collectively comprise at least one carbon atom that has more than one C—F bond.

7. The composition of claim 1 wherein R¹ comprises at least one carbon atom that has a C═C bond and at least one carbon atom that has a C—F bond.

8. The composition of claim 7 wherein R² comprises methyl, n-propyl, iso-propyl, n-butyl, t-butyl, t-amyl, propenyl, butenyl, pentenyl, or isomers thereof.

9. The composition of claim 1 wherein R¹ comprises at least one carbon atom that has both a C═C bond and a C—F bond.

10. The composition of claim 1 wherein R¹SnL¹₃ and R²SnL²₃ each comprise at least about 5% of the total Sn atoms in the composition.

11. The composition of claim 1 wherein L¹ and/or L² are a dialkylamide, an alkylsilylamide, an alkoxide, an alkylacetylide, or a combination thereof.

12. The composition of claim 1 wherein L¹ and L² are an alkoxide.

13. The composition of claim 1 wherein R¹SnL²₃ comprises 3,4,4-trifluorobut-4-enyltin tris(tert-butyl oxide) and R²SnL²₃ comprises but-4-enyltin tris(tert-butyl oxide).

14. The composition of claim 1 wherein R¹SnL²₃ comprises 3,4,4-trifluorobut-4-enyltin tris(tert-butyl oxide) and R²SnL²₃ comprises t-butyltin tris(tert-amyl oxide).

15. The composition of claim 1 wherein the blend further comprises R³SnL³₃, wherein R³ is an organo group with 1 to 31 carbon atoms that is different from R¹ and R² and forming a C—Sn bond, wherein R³SnL³₃ comprises at least about 1% of the total Sn atoms in the composition and L³ is a selected hydrolysable ligand.

16. The composition of claim 15 wherein R³ is selected from the group consisting of a fluorinated ligand free of unsaturated carbon-carbon bonds, a fluorinated ligand comprising a C═C bond, a fluorinated ligand comprising an aromatic group, a non-fluorinated ligand free of unsaturated carbon-carbon bonds, a non-fluorinated ligand comprising a C═C bond, and a non-fluorinated ligand comprising an aromatic group.

17. The composition of claim 15 wherein L¹, L², and/or L³ are a dialkylamide, an alkylsilylamide, an alkoxide, an alkylacetylide, or a combination thereof.

18. The composition of claim 15 wherein L¹, L² and L³ are an alkoxide.

19. The composition of claim 15 wherein R¹SnL²₃ comprises 3,4,4-trifluorobut-4-enyltin tris(tert-butyl oxide), R²SnL²₃ comprises t-butyltin tris(tert-amyl oxide), and R³SnL³₃ comprises methyltin tris(tert-amyl oxide).

20. A photoresist composition comprising an organic solvent and the composition of claim 1.

21. The photoresist composition of claim 20 wherein the organic solvent comprises an alcohol.

22. The photoresist composition of claim 20 wherein the organic solvent comprises a primary alcohol or a combination thereof.
